(19) United States
(12) Patent Application Publication
(10) Pub. No.: US 2019/0171103 A1
(43) Pub. Date: Jun. 6, 2019

(54) PHOTOSENSITIVE RESIN COMPOSITION, TRANSFER FILM, PROTECTIVE FILM FOR TOUCH PANEL, TOUCH PANEL, MANUFACTURING METHOD OF THE SAME, AND IMAGE DISPLAY APPARATUS

(71) Applicant: FUJIFILM Corporation, Tokyo (JP)

(72) Inventors: Tatsuya SHIMOYAMA, Shizuoka (JP); Hideyuki NAKAMURA, Shizuoka (JP)

(73) Assignee: FUJIFILM Corporation, Tokyo (JP)

(21) Appl. No.: 16/268,654

(22) Filed: Feb. 6, 2019

Related U.S. Application Data
(63) Continuation of application No. PCT/JP2017/022523, filed on Jun. 19, 2017.

(30) Foreign Application Priority Data
Aug. 30, 2016 (JP) 2016-168425

(51) Int. Cl. G03F 7/033; G03F 7/031; G03F 7/20; G03F 7/32; G03F 7/16; G03F 7/038; G06F 3/041

(52) U.S. Cl. CPC G03F 7/033; G03F 7/031; G03F 7/2037; G06F 2203/04103; G03F 7/16; G03F 7/038; G06F 3/041; G03F 7/322

(57) ABSTRACT

Provided is a photosensitive resin composition including: a photopolymerizable monomer including an ethylenically unsaturated group; a photopolymerization initiator; a polymer including a structural unit having a carboxylic acid anhydride structure; and a nitrogen-containing heterocyclic compound, and application thereof.

### CROSS-REFERENCE TO RELATED APPLICATION

This application is a Continuation of International Application No. PCT/JP2017/022523, filed Jun. 19, 2017, which claims priority to Japanese Patent Application No. 2016-168425 filed Aug. 30, 2016. Each of the above applications is hereby expressly incorporated by reference, in its entirety, into the present application.

### BACKGROUND OF THE INVENTION

### 1. Field of the Invention

The present disclosure relates to a photosensitive resin composition, a transfer film, a protective film for a touch panel, a touch panel, a manufacturing method of the same, and an image display apparatus.

### 2. Description of the Related Art

In the related art, a photosensitive resin composition has been known.

For example, a curable resin composition including an alkali soluble resin, and a di-or higher polyfunctional (meth)acrylate compound, in which the alkali soluble resin is at least two or more kinds of an alkali soluble resin (A) including an ethylenically unsaturated group on a side chain, and an alkali soluble resin (B) not including an ethylenically unsaturated group on a side chain, and the alkali soluble resin (B) is obtained by polymerizing a monomer component including an aromatic vinyl compound, and a maleic anhydride derivative and/or a hydrolyzate thereof, has been known as a curable resin composition which has extremely excellent electrical properties and applies a cured product having sufficient adhesiveness, surface hardness, and transparency (for example, see JP2015-160869A).

In addition, a technology of forming a protective film of an electrode for a touch panel using a photosensitive resin composition has been also known.

For example, a forming method of a protective film of an electrode for a touch panel capable of forming a protective film having sufficient rust inhibiting properties even with a small thickness, including: providing a photosensitive layer formed of a photosensitive resin composition including a binder polymer including a carboxyl group and in which an acid value is 30 mgKOH/g to 120 mgKOH/g, a photopolymerizable compound including at least three ethylenically unsaturated groups, and a photopolymerization initiator, on a substrate including an electrode for a touch panel, curing a predetermined portion of the photosensitive layer by emitting an actinic ray and removing a portion other than the predetermined portion, and forming a protective film formed of the cured product of the predetermined portion of the photosensitive layer covering a part or the entire electrode described above (for example, see JP5304973B).

### SUMMARY OF THE INVENTION

In general, a cured film is formed on a substrate by forming a photosensitive layer on a substrate, performing a pattern exposure with respect to the photosensitive layer formed on the substrate, and developing the pattern-exposed photosensitive layer, by using a photosensitive resin composition or a transfer film including a photosensitive layer including a temporary support and solid contents of the photosensitive resin composition.

Perspiration resistance (that is, resistance to perspiration may be required with respect to the cured film described above. For example, in a case of forming a protective film for a touch panel as the cured film described above, perspiration resistance is required with respect to the protective film for a touch panel to be formed (details thereof will be described later).

Regarding this point, from the studies of the inventors, it has been determined that perspiration resistance tends to be deteriorated in the cured film manufactured using a photosensitive resin composition disclosed in JP2015-160869A and JP5304973B.

In addition, the studies of the inventors, it has been determined that a development residue due to thermal fogging tends to be generated, in a case where a transfer film is manufactured by using the photosensitive resin composition disclosed in JP2015-160869A and JP5304973B, the cured film is formed using the manufactured transfer film, and laminating conditions at a high temperature (for example, equal to or higher than 120° C.) are applied in a stage of laminating the transfer film.

An object of a first aspect of the disclosure is to provide a photosensitive resin composition capable of forming a cured film having excellent perspiration resistance.

An object of a second aspect of the disclosure is to provide a transfer film capable of forming a cured film having excellent perspiration resistance, and capable of preventing generation of a development residue due to thermal fogging, even in a case where laminating conditions at a high temperature (for example, equal to or higher than 120° C.) are applied in a stage of laminating a transfer film, in a case of forming the cured film.

An object of a third aspect of the disclosure is to provide a protective film for a touch panel having excellent perspiration resistance.

An object of a fourth aspect of the disclosure is to provide a touch panel including the protective film for a touch panel.

An object of a fifth aspect of the disclosure is to provide an image display apparatus including the touch panel.

An object of a sixth aspect of the disclosure is to provide a manufacturing method of a touch panel capable of manufacturing the touch panel.

Means for achieving the objects described above include the following aspects.

<1> A photosensitive resin composition comprising: a photopolymerizable monomer including an ethylenically unsaturated group; a photopolymerization initiator; a polymer including a structural unit having a carboxylic acid anhydride structure; and a nitrogen-containing heterocyclic compound.

<2> The photosensitive resin composition according to <1>, in which the nitrogen-containing heterocyclic compound is at least one kind of azole compound selected from the group consisting of an imidazole component, a triazole compound, a tetrazole compound, a thiazole compound, and a thiadiazole compound.

<3> The photosensitive resin composition according to <1> or <2>, in which an acid anhydride value of the polymer including the structural unit having the carboxylic acid anhydride structure is 0.80 mmol/g to 5.00 mmol/g.

<4> The photosensitive resin composition according to any one of <1> to <3>, in which the polymer including the structural unit having the carboxylic acid anhydride structure further includes a structural unit derived from a styrene compound.

<5> The photosensitive resin composition according to any one of <1> to <4>, in which the structural unit having the carboxylic acid anhydride structure includes at least one of a structural unit represented by Formula a2-1 and a structural unit represented by Formula a2-2.

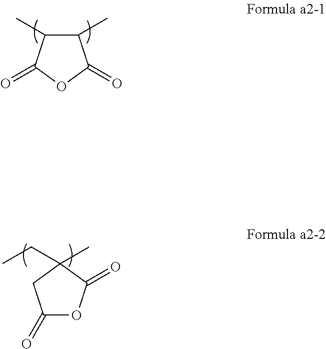

<6> The photosensitive resin composition according to any one of <1> to <5>, in which a content of the polymer including the structural unit including the carboxylic acid anhydride with respect to solid contents of the photosensitive resin composition is equal to or smaller than 30% by mass.

<7> The photosensitive resin composition according to any one of <1> to <6>, in which the nitrogen-containing heterocyclic compound includes at least one kind of azole compound selected from the group consisting of an imidazole compound, a triazole compound, and a tetrazole compound.

<8> The photosensitive resin composition according to any one of <1> to <7>, which is used for forming a protective film for a touch panel.

<9> A transfer film comprising: a temporary support; and a photosensitive layer including solid contents of the photosensitive resin composition according to any one of <1> to <8>.

<10> The transfer film according to <9>, in which a thickness of the photosensitive layer is equal to or smaller than 20 μm.

<11> The transfer film according to <9> or <10>, which is used for forming a protective film for a touch panel.

<12> A protective film for a touch panel which is a cured product of solid contents of the photosensitive resin composition according to <8>.

<13> A touch panel comprising: the protective film for a touch panel according to <12>.

<14> An image display apparatus comprising: the touch panel according to <13>.

<15> A manufacturing method of a touch panel comprising: a step of preparing a substrate for a touch panel including a structure in which at least one of an electrode for a touch panel or a wiring for a touch panel is disposed on the substrate; a step of forming a photosensitive layer on a surface of the substrate for a touch panel on a side where at least one of the electrode for a touch panel or the wiring for a touch panel is disposed, by using the photosensitive resin composition according to <8> or the transfer film according to <11>; a step of performing pattern-exposing on the photosensitive layer formed on the surface of the substrate for a touch panel; and a step of developing the pattern-exposed photosensitive layer to obtain a protective film for a touch panel which protects at least a part of at least one of the electrode for a touch panel or the wiring for a touch panel.

According to the first aspect of the disclosure, a photosensitive resin composition capable of forming a cured film having excellent perspiration resistance is provided.

According to the second aspect, a transfer film capable of forming a cured film having excellent perspiration resistance, and capable of preventing generation of a development residue due to thermal fogging, even in a case where laminating conditions at a high temperature (for example, equal to or higher than 120° C.) are applied in a stage of laminating a transfer film, in a case of forming the cured film.

According to the third aspect of the disclosure, a protective film for a touch panel having excellent perspiration resistance is provided.

According to the fourth aspect of the disclosure, a touch panel including the protective film for a touch panel is provided.

According to the fifth aspect of the disclosure, an image display apparatus including the touch panel is provided.

According to the sixth aspect of the disclosure, a manufacturing method of a touch panel capable of manufacturing the touch panel is provided.

### DESCRIPTION OF THE DRAWINGS

FIG. 1 is a schematic cross sectional view showing a specific example of a transfer film according to the second aspect of the disclosure.

FIG. 2 is a schematic cross sectional view showing a first specific example of a touch panel according to the fourth aspect of the disclosure.

FIG. 3 is a schematic cross sectional view showing a second specific example of the touch panel according to the fourth aspect of the disclosure.

### DESCRIPTION OF THE PREFERRED EMBODIMENTS

In this specification, a range of numerical values shown using “to” means a range including numerical values before and after “to” as a lower limit value and an upper limit value.

In this specification, in a case where a plurality of substances corresponding to components are present in the composition, the amount of each component in the composition means a total amount of the plurality of substances present in the composition, unless otherwise noted.

In this specification, a term “step” not only includes an independent step, but also includes a step, in a case where the step may not be distinguished from the other step, as long as the expected object of the step is achieved.

In this specification, “(meth)acrylic acid” has a concept including both acrylic acid and a methacrylic acid, “(meth)acrylate” has a concept including both acrylate and methacrylate, and “(meth)acryloyl group” has a concept including both acryloyl group and methacryloyl group.

In the specification, a rate of the structural unit of the polymer indicates a molar ratio, unless otherwise noted.

In the specification, the “solid contents of a photosensitive resin composition” means components other than a solvent in the photosensitive resin composition, and the “amount of solid contents of the photosensitive resin composition” means a total amount of solid contents in the photosensitive resin composition.

In the specification, “light” has a concept including active energy ray such as a γ ray, a β ray, an electron ray, an ultraviolet ray, a visible light ray, and an infrared ray.

In the specification, a “transparent” state means that a minimum light transmittance at a wavelength of 400 nm to 800 nm is equal to or greater than 80% (preferably equal to or greater than 90% and more preferably equal to or greater than 95%).

[Photosensitive Resin Composition]

A photosensitive resin composition of the disclosure includes a photopolymerizable monomer including an ethylenically unsaturated group (hereinafter, also simply referred to as a “photopolymerizable monomer”), a photopolymerization initiator, a polymer including a structural unit having a carboxylic acid anhydride structure (hereinafter, also referred to as a “specific polymer”), and a nitrogen-containing heterocyclic compound.

According to the photosensitive resin composition of the disclosure, a cured film having excellent perspiration resistance (for example, protective film for a touch panel. The same applies hereinafter) can be formed.

A reason for exhibiting an effect of perspiration resistance of a cured film is not clear, and the following reason is considered.

In the cured film, the specific polymer and the nitrogen-containing heterocyclic compound are included. In a case where perspiration is in contact with this cured film, the carboxylic acid anhydride structure of the specific polymer in the cured film is ring-opened due to moisture in the perspiration. It is thought that the nitrogen-containing heterocyclic compound in the cured film functions as a catalyst with respect to ring opening of the carboxylic acid anhydride structure. It is thought that perspiration in contact with the cured film is trapped in the cured film (that is, an effect of perspiration resistance of the cured film is exhibited), due to a mechanism of the ring opening of the carboxylic acid anhydride structure.

However, the photosensitive resin composition of the disclosure is not limited to the reason described above.

In a case where the nitrogen-containing heterocyclic compound of the disclosure is excluded from the photosensitive resin composition of the disclosure, the perspiration resistance of the cured film is deteriorated (for example, see Comparative Example 2 which will be described later). It is assumed that this reason is because a degree of ring opening of the carboxylic acid anhydride structure of the specific polymer becomes insufficient due to absence of the nitrogen-containing heterocyclic compound functioning as a catalyst with respect to the ring opening of the carboxylic acid anhydride structure, and accordingly, an effect of trapping perspiration becomes insufficient.

Even in a case where the specific polymer is excluded from the photosensitive resin composition of the disclosure, perspiration resistance of the cured film is deteriorated (for example, see Comparative Example 3 which will be described later). It is assumed that this reason is because the carboxylic acid anhydride structure trapping perspiration due to the ring opening is not present.

In addition, in the photosensitive resin composition of the disclosure, even in a case where the structural unit having the carboxylic acid anhydride structure in the specific polymer is changed to a structural unit having a half ester structure of dicarboxylic acid, perspiration resistance of the cured film is deteriorated (for example, see Comparative Examples 4 and 5 which will be described later). It is assumed that this reason is because the effect of trapping perspiration becomes insufficient due to the absence of the carboxylic acid anhydride structure.

The photosensitive resin composition of the disclosure is applied on a substrate (for example, a glass substrate, a resin substrate, or a substrate for a touch panel which will be described later) and can be used for forming a photosensitive layer directly on the substrate.

In addition, the photosensitive resin composition can also be used for forming a photosensitive layer of a transfer film including a temporary support and a photosensitive layer.

In a case of using the photosensitive resin composition of the disclosure for forming a photosensitive layer of a transfer film, the following effect is also exhibited.

That is, in a case of forming a cured film using the transfer film, and even in a case where laminating conditions at a high temperature (for example, equal to or higher than 120° C.) are applied in a stage of laminating a transfer film, the generation of a development residue due to thermal fogging is prevented.

Hereinafter, such an effect is also simply referred to as an “effect of development residue prevention”.

The reason of exhibiting the effect of development residue prevention is not clear and is assumed as follows. However, the photosensitive resin composition of the disclosure is not limited to the following reason.

It is thought that the development residue due to thermal fogging is generated due to insufficient developability (that is, solubility to a developer) of an unexposed portion of the photosensitive layer, in a case of transferring the photosensitive layer of the transfer film onto a substrate under the laminating conditions at a high temperature (for example, equal to or higher than 120° C.), and exposing and developing the photosensitive layer transferred onto the substrate. The unexposed portion of the photosensitive layer is an uncured portion and is originally a portion to be removed by a developer (that is, portion to be dissolved in a developer).

Regarding the development residue due to thermal fogging, the photosensitive resin composition of the disclosure includes the specific polymer and the nitrogen-containing heterocyclic compound. Accordingly, in a case where a developer is in contact with the photosensitive layer including solid contents of the photosensitive resin composition of the disclosure, the nitrogen-containing heterocyclic compound in the photosensitive layer functions as a catalyst, and accordingly, the carboxylic acid anhydride structure of the specific polymer in the photosensitive layer is ring-opened due to moisture in a developer and a carboxyl group is generated. It is thought that this carboxyl group causes the improvement of developability (that is, solubility to a developer) of the unexposed portion of the photosensitive layer, and accordingly, the generation of the development residue due to thermal fogging is prevented.

It is thought that, on a surface of the exposed portion (that is, portion to be a cured film) of the photosensitive layer and the vicinity thereof, the carboxyl group generated due to a contact between the developer and the photosensitive layer returns to the carboxylic acid anhydride structure again due to drying (preferably post baking) after the development. In addition, it is thought that, in the inner portion (portion not in contact with the developer) of the exposed portion of the photosensitive layer, the carboxylic acid anhydride structure is not ring-opened and remains as it is. It is thought that, in the cured film, the effect of perspiration resistance improvement described above is exhibited, due to the operation of the carboxylic acid anhydride structure and the nitrogen-containing heterocyclic compound.

The photosensitive resin composition of the disclosure is used for forming the cured film requiring perspiration resistance, without particular limitations.

As an example of the cured film requiring perspiration resistance, a protective film for a touch panel is used.

Hereinafter, a touch panel and a protective film for a touch panel will be described.

As an electronic apparatus such as a mobile phone, a car navigator, a personal computer, a ticket vending machine, or a terminal device of a bank, an electronic apparatus in which a touch panel (that is, a tablet type input device) is disposed on a surface of an image display apparatus (for example, a liquid crystal display apparatus) including an image display region is known.

In such an electronic apparatus, information is input by touching a portion corresponding to an instruction image of the touch panel with a finger, while referring the instruction image displayed on the image display region.

The touch panel includes a substrate for a touch panel having a structure in which at least one of an electrode for a touch panel and a wiring for a touch panel (hereinafter, also referred to as “electrode and the like”) is disposed on a substrate, and a protective film for a touch panel which covers at least a part of the electrode and the like directly or through other layers.

As the electrode for a touch panel, a transparent electrode pattern provided in an image display region is used, for example.

As the wiring for a touch panel, a leading wiring provided in a region other than the image display region (hereinafter, also referred to as a “frame portion” or an “image non-display region”) is used, for example.

The leading wiring is also referred to as a lead-out wiring.

In the touch panel, the electrode and the like under the protective film for a touch panel may be corroded due to penetration of perspiration of human into the protective film for a touch panel. In order to prevent such corrosion, perspiration resistance is required for the protective film for a touch panel.

Particularly, in recent years, a decrease in thickness (that is, thinning) of the protective film for a touch panel is required, from viewpoints of weight reduction of the touch panel and improvement of transmittance of the touch panel. As the thickness of the protective film for a touch panel decreases, the perspiration resistance of the protective film for a touch panel easily decreases.

From the above-mentioned circumstance, the perspiration resistance of the protective film for a touch panel is practically important performance.

Therefore, the photosensitive resin composition of the disclosure capable of forming a cured film having excellent perspiration resistance is particularly preferably used for forming the protective film for a touch panel as the cured film.

As the aspect of forming the protective film for a touch panel using the photosensitive resin composition of the disclosure, the following aspect 1 and aspect 2 are used.

Aspect 1. an aspect of forming a protective film for a touch panel by applying and drying the photosensitive resin composition of the disclosure onto a substrate for a touch panel to form a photosensitive layer, and subsequently performing exposure and development with respect to the formed photosensitive layer.

Aspect 2. an aspect of forming a protective film for a touch panel by applying and drying the photosensitive resin composition of the disclosure onto a temporary support to form a photosensitive layer, thereby manufacturing a transfer film, laminating the manufactured transfer film onto a substrate for a touch panel to transfer the photosensitive layer of the transfer film onto the substrate for a touch panel, and subsequently performing exposure and development with respect to the photosensitive layer transferred onto the substrate for a touch panel.

The photosensitive resin composition of the disclosure may be used for forming a cured film other than the protective film for a touch panel.

Hereinafter, each component which can be included in the photosensitive resin composition of the disclosure will be described.

<Specific Polymer>

The photosensitive resin composition of the disclosure includes a specific polymer (that is, polymer including a structural unit having a carboxylic acid anhydride structure).

As described above the specific polymer and a nitrogen-containing heterocyclic compound which will be described later contribute to the effect of perspiration resistance improvement of the cured film and the effect of development residue prevention in a case of using the transfer film.

A weight-average molecular weight of the specific polymer is preferably 1,000 to 500,000, more preferably 3,000 to 300,000, even more preferably 5,000 to 200,000, still preferably 5,000 to 100,000, still more preferably 5,000 to 50,000, and particularly preferably 5,000 to 30,000.

In the specification, the weight-average molecular weight (Mw) is measured by gel permeation chromatography (GPC).

In the measurement of Mw, a calibration curve is drawn from eight samples of “STANDARD SAMPLES TSK standard, polystyrene” manufactured by Tosoh Corporation: “F-40”, “F-20”, “F-4”, “F-1”, “A-5000”, “A-2500”, “A-1000”, “n-propylbenzene”.

Conditions

GPC: HLC (registered trademark)-8020 GPC (manufactured by Tosoh Corporation)

Column: TSKgel (registered trademark), three Super Multipore HZ-H (manufactured by Tosoh Corporation, 4.6 mmID×15 cm)

Eluent: Tetrahydrofuran (THF)

Sample Concentration: 0.45% by mass

Flow rate: 0.35 ml/min

Sample injected amount: 10 μL

Measurement temperature: 40° C.

Detector: differential refractometer (RI)

(Structural Unit Having Carboxylic Acid Anhydride Structure)

The specific polymer includes at least one kind of a structural unit having a carboxylic acid anhydride structure.

The structural unit having a carboxylic acid anhydride structure preferably includes only one kind of a carboxylic acid anhydride structure.

The carboxylic acid anhydride structure may be any of a chain carboxylic acid anhydride structure and a cyclic carboxylic acid anhydride structure, and the cyclic carboxylic acid anhydride structure is preferable.

The ring of the cyclic carboxylic acid anhydride structure is preferably 5- to 7-membered ring, more preferably 5- or 6-membered ring, and more preferably 5-membered ring.

In addition, the cyclic carboxylic acid anhydride structure may form a polycyclic structure by annelation or bonding to other cyclic structures, but it is preferable that a polycyclic structure is not formed.

In a case where a polycyclic structure is formed by annelation or bonding of other cyclic structures to the cyclic carboxylic acid anhydride structure, a bicyclo structure or Spiro structure is preferable as the polycyclic structure.

In the polycyclic structure, the number of other cyclic structures forming a ring with or bonded to the cyclic carboxylic acid anhydride structure is preferably 1 to 5 and more preferably 1 to 3.

Examples of the other cyclic structure include a cyclic hydrocarbon group having 3 to 20 carbon atoms and a heterocyclic group having 3 to 20 carbon atoms.

The heterocyclic group is not particularly limited, and examples thereof include an aliphatic heterocyclic group and an aromatic heterocyclic group.

In addition, the heterocyclic group is preferably 5-membered ring or 6-membered ring and particularly preferably 5-membered ring.

As the heterocyclic group, a heterocyclic group including at least one oxygen atom (for example, an oxolane ring, an oxane ring, or a dioxane ring) is preferable.

The carboxylic acid anhydride structure may include or may not include a substituent, and it is preferable that the carboxylic acid anhydride structure does not include a substituent.

The substituent is not particularly limited, and examples thereof include an alkyl group having 1 to 8 carbon atoms, a cycloalkyl group having 3 to 7 carbon atoms, an alkoxy group having 1 to 8 carbon atoms, an alkoxycarbonyl group having 2 to 8 carbon atoms, an carboxyl group, a halogen atom, a hydroxyl group, a cyano group, and an alkyl group having 1 to 8 carbon atoms or a cyano group is preferable.

As the alkyl group having 1 to 8 carbon atoms, a linear alkyl group having 1 to 6 carbon atoms, a branched alkyl group having 3 to 6 carbon atoms, or a cyclic alkyl group having 3 to 6 carbon atoms is preferable, and a linear alkyl group having 1 to 3 carbon atoms is more preferable.

In a case where the carboxylic acid anhydride structure includes a substituent, the number of substituents is not particularly limited, and is preferably 1 to 4 and more preferably 1 or 2.

In a case where the carboxylic acid anhydride structure includes a plurality of substituents, the plurality of substituents may be the same as each other or different from each other.

In addition, in a case where the annulation of the other cyclic structure is performed to the carboxylic acid anhydride structure, the other cyclic structure may not include a substituent.

The structural unit having a carboxylic acid anhydride structure is preferably a structural unit including divalent group excluding two hydrogen atoms from a compound represented by Formula 2 in a main chain, or a structural unit in which monovalent group excluding one hydrogen atom from the compound represented by Formula 2 is bonded to a main chain directly or through a divalent linking group.

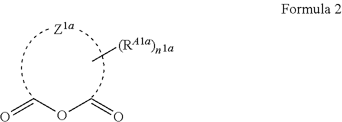

In Formula 2, R^{A1a} represents a substituent, and n^{1a} R^{A1a,}'s be the same as or different from each other.

Z^{1a} represents a divalent group forming a ring including —C(═O)—O—C(═O)—. n^{1a} represents an integer equal to or greater than 0.

As the substituent represented by R^{A1a}, a component same as a substituent which may be included in the carboxylic acid anhydride structure is used, and the preferred range is also same.

Z^{1a} is preferably an alkylene group having 2 to 4 carbon atoms, more preferably an alkylene group having 2 or 3 carbon atoms, and particularly preferably an alkylene group having 2 carbon atoms.

A partial structure represented by Formula 2 may form a polycyclic structure by annelation or bonding to other cyclic structures, but it is preferable that a polycyclic structure is not formed.

As the other cyclic structure here, a structure same as the other cyclic structure described above which may form a ring with or be bonded to the carboxylic acid anhydride structure is used, and the preferred range is also same.

n^{1a} represents an integer equal to or greater than 0.

In a case where Z^{1a} represents an alkylene group having 2 to 4 carbon atoms, n^{1a} is preferably an integer of 0 to 4, more preferably an integer of 0 to 2, and even more preferably 0.

In a case where n^{1a} represents an integer equal to or greater than 2, a plurality of R^{A1a}'s may be same as or different from each other. In addition, a plurality of R^{A1a}'s may be bonded to each other to form a ring, but it is preferable that a plurality of R^{A1a}'s are not bonded to each other to form a ring.

The structural unit having a carboxylic acid anhydride structure is preferably a structural unit derived from an unsaturated carboxylic acid anhydride, more preferably a structural unit derived from an unsaturated cyclic carboxylic acid anhydride, even more preferably a structural unit derived from an unsaturated aliphatic cyclic carboxylic acid anhydride, still preferably a structural unit derived from a maleic anhydride or an itaconic acid anhydride, and particularly preferably a structural unit derived from a maleic anhydride.

Hereinafter, specific examples of the structural unit having a carboxylic acid anhydride structure are described, but the structural unit having a carboxylic acid anhydride structure is not limited to these specific examples.

In the following structural units, Rx represents a hydrogen atom, a methyl group, a CH₂OH group, or a CF₃ group, and Me represents a methyl group.

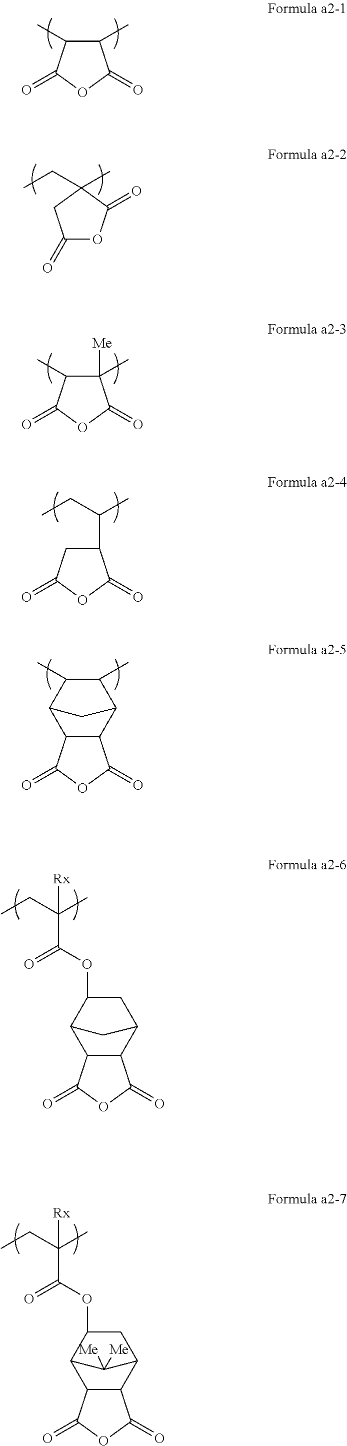

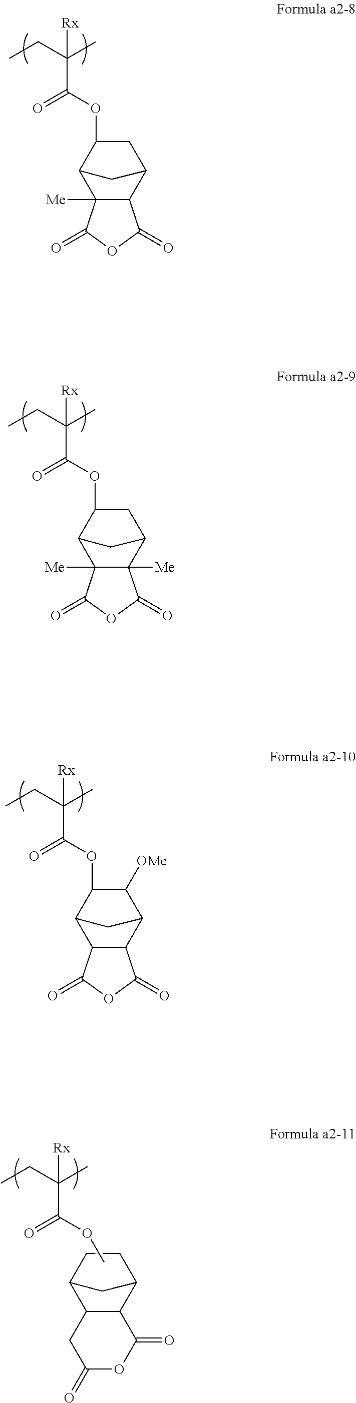

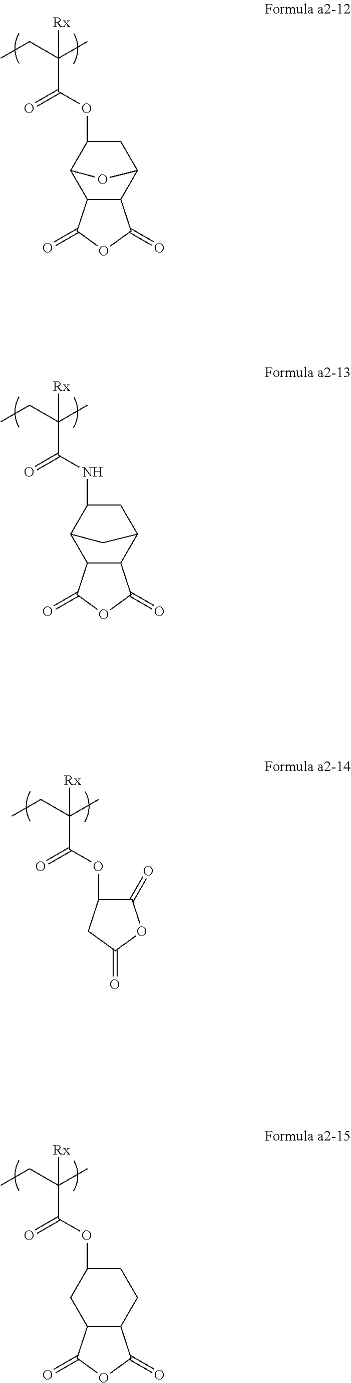

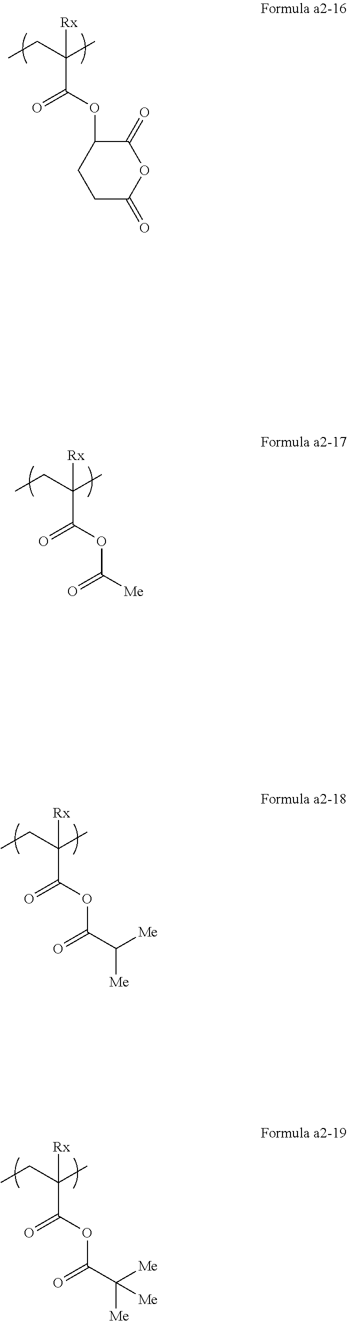

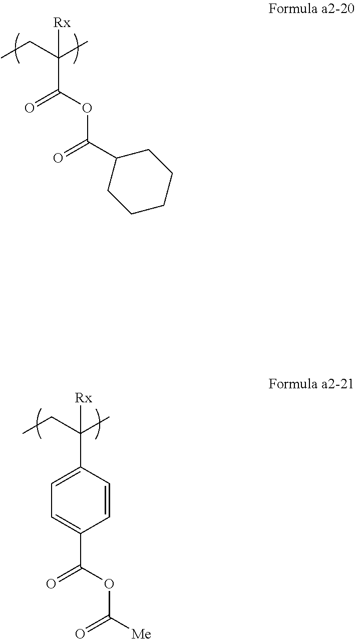

The structural unit having a carboxylic acid anhydride structure is preferably at least one kind of the structural units represented by Formula a2-1 to Formula a2-21, and more preferably one kind of the structural units represented by Formula a2-1 to Formula a2-21.

From viewpoints of perspiration resistance improvement of the cured film and development residue prevention in a case of using the transfer film, the structural unit having a carboxylic acid anhydride structure preferably includes at least one of the structural unit represented by Formula a2-1 or the structural unit represented by Formula a2-2, and more preferably includes the structural unit represented by Formula a2-1.

A content of the structural unit having a carboxylic acid anhydride structure in the specific polymer (a total content, in a case of two or more kinds of structural units. The same applies hereinafter) is preferably 5% by mol to 60% by mol, more preferably 5% by mol to 40% by mol, and even more preferably 10% by mol to 35% by mol, with respect to a total content of all of the structural units included in the specific polymer.

(Structural Unit Represented By Formula 1)

The specific polymer preferably includes at least one kind of structural unit represented by Formula 1. Accordingly, hydrophobicity and hardness of the cured film to be formed are further improved.

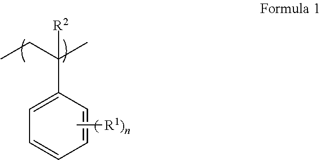

In Formula 1, R¹ represents a hydroxyl group, an alkyl group, an aryl group, an alkoxy group, a carboxyl group, or a halogen atom, R² represents a hydrogen atom, an alkyl group, or an aryl group, and n represents an integer of 0 to 5. In a case where n is an integer equal to or greater than 2, two or more R¹'s may be the same as or different from each other.

R¹ is preferably an alkyl group having 1 to 10 carbon atoms, an aryl group having 6 to 12 carbon atoms, an alkoxy group having 1 to 10 carbon atoms, a carboxyl group, an F atom, a Cl atom, a Br atom, or an I atom, and more preferably an alkyl group having 1 to 4 carbon atoms, a phenyl group, an alkoxy group having 1 to 4 carbon atoms, a Cl atom, or a Br atom.

R² is preferably a hydrogen atom, an alkyl group having 1 to 10 carbon atoms, or an aryl group having 6 to 12 carbon atoms, more preferably a hydrogen atom or an alkyl group having 1 to 4 carbon atoms, even more preferably a hydrogen atom, a methyl group, or an ethyl group, and particularly preferably a hydrogen atom.

n is preferably an integer of 0 to 3, more preferably 0 or 1, and even more preferably 0.

The structural unit represented by Formula 1 is preferably a structural unit derived from a styrene compound.

Examples of the styrene compound include styrene, p-methylstyrene, α-methylstyrene, α,p-dimethylstyrene, p-ethylstyrene, p-t-butylstyrene, and 1,1-diphenylethylene, styrene or a-methylstyrene is preferable, and styrene is particularly preferable.

The styrene compound for forming the structural unit represented by Formula 1 may be only one kind or two or more kinds thereof.

In a case where the specific polymer includes the structural unit represented by Formula 1, a content of the structural unit represented by Formula 1 in the specific polymer (a total content, in a case of two or more kinds of structural units. The same applies hereinafter) is preferably 20% by mol to 90% by mol, more preferably 30% by mol to 90% by mol, and even more preferably 40% by mol to 90% by mol, with respect to a total content of all of the structural units included in the specific polymer.

In a case where the specific polymer includes the structural unit represented by Formula 1, a total content of the structural unit represented by Formula 1 and the structural unit having a carboxylic acid anhydride structure in the specific polymer is preferably equal to or greater than 70% by mass, more preferably equal to or greater than 90% by mass, and even more preferably equal to or greater than 95% by mass, with respect to a total amount of the specific polymer.

The upper limit of the total content of the structural unit represented by Formula 1 and the structural unit having a carboxylic acid anhydride structure is not particularly limited. That is, the total content may be 100% by mass.

(Other Structural Unit)

The specific polymer may include at least one kind of structural units other than the structural unit having a carboxylic acid anhydride structure and the structural unit represented by Formula 1.

It is preferable that the other structural unit does not include an acid group.

The other structural unit is not particularly limited, and a structural unit derived from a monofunctional ethylenically unsaturated compound is used.

As the monofunctional ethylenically unsaturated compound, a well-known compound can be used without particular limitations, and examples thereof include a (meth)acrylic acid derivative such as methyl (meth)acrylate, ethyl (meth)acrylate, n-butyl (meth)acrylate, 2-ethylhexyl (meth)acrylate, carbitol (meth)acrylate, cyclohexyl (meth)acrylate, benzyl (meth)acrylate, and epoxy (meth)acrylate; an N-vinyl compound such as N-vinyl pyrrolidone or N-vinyl caprolactam; and a derivative of an allyl compound such as allyl glycidyl ether.

A content of the other structural unit in the specific polymer (a total content, in a case of two or more kinds of structural units) is preferably 0% by mass to 10% by mass, more preferably 0% by mass to 5% by mass, and even more preferably 0% by mass to 2% by mass, with respect to a total amount of the specific polymer.

(Content)

The content of the specific polymer in the photosensitive resin composition of the disclosure is preferably equal to or smaller than 30% by mass and more preferably 0.1% by mass to 30% by mass, with respect to the solid contents of the photosensitive resin composition.

In a case where the content of the specific polymer is equal to or smaller than 30% by mass, the content of the photopolymerizable monomer (and other polymers used if necessary) is easily ensured, and thus, photosensitivity (that is, photocuring properties) of the photosensitive resin composition and hardness of the cured film are further improved.

The content of the specific polymer is more preferably equal to or smaller than 20% by mass.

In a case where the content of the specific polymer is equal to or greater than 0.1% by mass, perspiration resistance of the cured film is further improved.

The content of the specific polymer is more preferably equal to or greater than 0.2% by mass, even more preferably equal to or greater than 0.5% by mass, and particularly preferably equal to or greater than 1% by mass, from a viewpoint of further improving the perspiration resistance of the cured film.

(Acid Anhydride Value)

An acid anhydride value of the specific polymer is preferably 0.80 mmol/g to 5.00 mmol/g, more preferably 0.90 mmol/g to 3.00 mmol/g, and particularly preferably 1.00 mmol/g to 2.00 mmol/g.

In the specification, the acid anhydride value means the number of the carboxylic acid anhydride structures per 1 g of the specific polymer shown with millimole (mmol).

In a case where the acid anhydride value of the specific polymer is equal to or greater than 0.80 mmol/g, the perspiration resistance of the cured film is further improved. It is thought that this reason is because an effect of trapping the perspiration is more effectively exhibited.

In a case where the acid anhydride value of the specific polymer is equal to or smaller than 5.00 mmol/g, the perspiration resistance of the cured film is further improved. It is thought that this reason is because the cured film becomes further hydrophobic.

In the specification, the acid anhydride value of the specific polymer is obtained by measuring a reaction amount of the carboxylic acid anhydride structure and octyl amine. Specifically, the acid anhydride value of the specific polymer is obtained by the following method.

First, the following solution A and the following solution B are prepared.

Solution A: methyl propylene glycol (MFG) solution having 10% by mass of octyl amine

Solution B: reaction liquid of specific polymer and solution A

The solution B is prepared by stirring a mixed solution of the specific polymer and the solution A at room temperature (25° C.) for 2 hours and completing the reaction between the specific polymer and the solution A.

In the preparation of the solution B, a mixing ratio of the specific polymer and the solution A in the mixed solution is set so that the acid amount (mmol) of the specific polymer and the amine amount (mmol) of the solution A coincide with each other or the amine amount (mmol) of the solution A is greater than the acid amount (mmol) of the specific polymer.

Here, the acid amount (mmol) of the specific polymer means a total acid amount (mmol) in a state where the carboxylic acid anhydride structure in the specific polymer is subjected to hydrolysis.

The acid amount (mmol) of the specific polymer is obtained from the sum of a total acid value (mmol/g) of the specific polymer in a state where the carboxylic acid anhydride structure in the specific polymer is subjected to hydrolysis, and a weight (g) of the specific polymer.

The amine amount (mmol) of the solution A is obtained from the sum of a valence (mmol/g) of amine of the solution A and a weight (g) of the solution A.

Next, by performing titration of the solution A and the solution B with 0.5 mol/L hydrochloric acid aqueous solution, respectively, a valence A (mmol/g) of amine of the solution A and a valence B (mmol/g) of amine of the solution B are respectively calculated.

The acid anhydride value (mmol/g) of the specific polymer is calculated by the following calculation equation, based on the valence A (mmol/g) of amine of the solution A and the valence B (mmol/g) of amine of the solution B.

Anhydride amount (mmol) of solution B=valence A (mmol/g) of amine of solution A×weight (g) of solution A used for preparation of solution B−valence B (mmol/g) of amine of the solution B×(weight (g) of solution A used for preparation of solution B+weight (g) of specific polymer used for preparation of solution B)

Acid anhydride value (mmol/g) of specific polymer=anhydride amount (mmol) of solution B/weight (g) of specific polymer used for preparation of solution B

The acid value in the specification means a value measured according to a method disclosed in JIS K0070 (1992).

<Nitrogen-Containing Heterocyclic Compound>

The photosensitive resin composition of the disclosure includes at least one kind of the nitrogen-containing heterocyclic compound.

The nitrogen-containing heterocyclic compound and the specific polymer described above contribute to improvement of perspiration resistance of the cured film and prevention of a development residue, in a case of using the transfer film in the photosensitive layer, as described above.

Examples of the nitrogen-containing heterocyclic compound include an azole compound (that is, nitrogen-containing 5-membered ring compound), and a nitrogen-containing 6-membered ring compound, and an azole compound is preferable, from viewpoints of an effect of the improvement of perspiration resistance of the cured film and prevention of a development residue, in a case of using the transfer film.

The nitrogen-containing heterocyclic compound is more preferably at least one kind of an azole compound selected from the group consisting of an imidazole compound, a triazole compound, a tetrazole compound, a thiazole compound, and a thiadiazole compound.

Examples of the imidazole compound include imidazole, benzimidazole, 2-methylimidazole, 2-mercaptobenzimidazole, 5-amino-2-mercaptobenzimidazole, and 5-methylbenzimidazole.

Examples of the triazole compound include 1,2,4-triazole, benzotriazole, 1H-benzotriazole-1-acetonitrile, benzotriazole-5-carboxylic acid, 1H-benzotriazole-1-methanol, carboxybenzotriazole, 3-mercapto 1,2,4-triazole, 3-amino-5-mercapto -1,2,4-triazole, 1-[N,N-bis (2-ethylhexyl) aminomethyl] benzotriazole, 3-amino-5-methylthio-1H-1,2,4-triazole, 2,2′-[[(methyl-1 H-benzotriazol-1-yl) methyl] imino] bisethanol, 1-(2,3-dicarboxypropyl) benzotriazole, 1-[(2-ethylhexylamino) methyl] benzotriazole, 2,6-bis [(1H-benzotriazol-1-yl) methyl]-4-methylphenol, and 1-(1′,2′-dicarboxyethyl) benzotriazole.

Examples of the tetrazole compound include 1H-tetrazole, 5-amino-1H-tetrazole, 5-methyl-1H-tetrazole, 1-methyl-5-ethyl-tetrazole, 1-methyl-5-mercapto-tetrazole, 1-carboxymethyl-5-mercapto-tetrazole, 5-mercapto-1-phenyl- 1 H-tetrazole, and 5-phenyl- 1H-tetrazole.

As the tetrazole compound, 1H-tetrazole, 5-amino-1H-tetrazole, or 1-methyl-5-mercapto-1H-tetrazole is particularly preferable, from a viewpoint of further improving perspiration resistance of the cured film.

Examples of the thiazole compound include thiazole, benzothiazole, and 2-aminobenzothiazole.

Examples of the thiadiazole compound include thiadiazole, 2-amino-5-mercapto-1,3,4-thiadiazole, 2,1,3-benzothiadiazole, 1,3,4-thiadiazole-2,5-dithiol, 2-mercapto-5-methylthio- 1,3,4-thiadiazole, 2-mercapto-1,3,4-thiadiazole, 2-amino-5-methylthio- 1,3,4-thiadiazole, and 5-amino-1,2,3-thiadiazole.

The nitrogen-containing heterocyclic compound preferably includes at least one kind of the azole compound selected from the group consisting of an imidazole compound, a triazole compounds, and a tetrazole compound, from a viewpoint of further improving perspiration resistance of the cured film.

A molecular weight of the nitrogen-containing heterocyclic compound is not particularly limited, and the molecular weight of the nitrogen-containing heterocyclic compound is preferably equal to or smaller than 1,000, more preferably equal to or smaller than 500, and even more preferably equal to or smaller than 300, and particularly preferably equal to or smaller than 200.

The content of the nitrogen-containing heterocyclic compound in the photosensitive resin composition of the disclosure is preferably 0.1% by mass to 8% by mass, more preferably 0.1% by mass to 5% by mass, even more preferably 0.2% by mass to 3% by mass, still more preferably 0.2% by mass to 2% by mass, and particularly preferably 0.2% by mass to 1% by mass, with respect to the solid contents of the photosensitive resin composition, from a viewpoint of further improving the perspiration resistance of the cured film and a viewpoint of preventing the development residue, in a case of using the transfer film.

In the photosensitive resin composition of the disclosure, a mass ratio of the content mass of the nitrogen-containing heterocyclic compound with respect to a total content mass of the specific polymer and the nitrogen-containing heterocyclic compound [content mass of nitrogen-containing heterocyclic compound/total content mass of specific polymer and nitrogen-containing heterocyclic compound] is preferably 0.01 to 0.70, more preferably 0.01 to 0.50, even more preferably equal to or greater than 0.01 and smaller than 0.50, still more preferably 0.03 to 0.40, and particularly preferably 0.05 to 0.40, from a viewpoint of further improving the perspiration resistance of the cured film and a viewpoint of preventing the development residue, in a case of using the transfer film.

A total content of the specific polymer and the nitrogen-containing heterocyclic compound in the photosensitive resin composition of the disclosure is preferably 0.1% by mass to 35% by mass, more preferably 1% by mass to 25% by mass, even more preferably 1% by mass to 20% by mass, and particularly preferably 2% by mass to 10% by mass, with respect to the solid contents of the photosensitive resin composition of the disclosure.

<Photopolymerizable Monomer>

The photosensitive resin composition of the disclosure includes at least one kind of the photopolymerizable monomer (that is, photopolymerizable monomer including an ethylenically unsaturated group).

The photopolymerizable monomer is a component contributing to photosensitivity of a composition (that is, photocuring properties) and hardness of the cured film.

The photopolymerizable monomer preferably includes di- or higher functional photopolymerizable monomer.

Here, the di- or higher functional photopolymerizable monomer means a photopolymerizable monomer including two or more of ethylenically unsaturated groups in one molecule.

The ethylenically unsaturated group is more preferably a (meth)acryloyl group.

The photopolymerizable monomer is preferably (meth)acrylate.

The photosensitive resin composition of the disclosure particularly preferably includes a difunctional photopolymerizable monomer (preferably, difunctional (meth)acrylate) and tri- or higher functional photopolymerizable monomer (preferably, tri- or higher functional (meth)acrylate), from a viewpoint of further improving the perspiration resistance of the cured film.

The difunctional photopolymerizable monomer is not particularly limited and can be suitably selected from well-known compounds.

Examples of the difunctional photopolymerizable monomer include tricyclodecane dimethanol di(meth) acrylate, tricyclodecane dimenanol di(meth) acrylate, 1,9-nonanediol di(meth)acrylate, 1,6-hexanediol and di(meth)acrylate.

More specific examples of the difunctional photopolymerizable monomer include tricyclodecanedimethanol diacrylate (A-DCP manufactured by Shin-Nakamura Chemical Co., Ltd.), tricyclodecanedimenanol dimethacrylate (DCP manufactured by Shin-Nakamura Chemical Co., Ltd.), 1,9-nonanediol diacrylate (A-NOD-N manufactured by Shin-Nakamura Chemical Co., Ltd.), and 1,6-hexanediol diacrylate (A-HD-N manufactured by Shin-Nakamura Chemical Co., Ltd.).

The tri- or higher functional photopolymerizable monomer is not particularly limited and can be suitably selected from well-known compounds.

Examples of the tri- or higher functional photopolymerizable monomer include dipentaerythritol (tri/tetra/penta/hexa) (meth)acrylate, pentaerythritol (tri/tetra) (meth)acrylate, trimethylolpropane tri(meth)acrylate, ditrimethylolpropane tetra(meth)acrylate, isocyanuric acid (meth)acrylate, and a (meth)acrylate compound of a glycerin tri(meth)acrylate skeleton.

Here, the “(tri/tetra/penta/hexa) (meth)acrylate” has a concept including tri(meth)acrylate, tetra(meth)acrylate, penta(meth)acrylate, and hexa(meth)acrylate, and the “(tri/tetra) (meth)acrylate” has a concept including tri(meth)acrylate and tetra(meth)acrylate.

Examples of the photopolymerizable monomer include a caprolactone-modified compound of a (meth)acrylate compound (KAYARAD (registered trademark) DPCA-20 manufactured by Nippon Kayaku Co., Ltd., A-9300-1CL manufactured by Shin-Nakamura Chemical Co., Ltd.), an alkylene oxide-modified compound of a (meth)acrylate compound (KAYARAD RP-1040 manufactured by Nippon Kayaku Co., Ltd., ATM-35E, A-9300 manufactured by Shin-Nakamura Chemical Co., Ltd., EBECRYL (registered trademark) 135 manufactured by Daicel-Allnex Ltd.), and ethoxylated glycerin triacrylate (A-GLY-9E manufactured by Shin-Nakamura Chemical Co., Ltd.).

As the photopolymerizable monomer, urethane (meth)acrylate (preferably tri- or higher functional urethane (meth)acrylate) is also used.

Examples of the tri- or higher functional urethane (meth)acrylate include 8UX-015A (manufactured by Taisei Fine Chemical Co., Ltd.), UA-32P (manufactured by Shin-Nakamura Chemical Co., Ltd.), and UA-1100H (manufactured by Shin-Nakamura Chemical Co., Ltd.).

The photopolymerizable monomer preferably includes a polymerizable monomer including an acid group, from viewpoints of improving developability and improving perspiration resistance of the cured film.

Examples of the acid group include a phosphoric acid group, a sulfonic acid group, and a carboxyl group, and a carboxyl group is preferable.

Examples of the photopolymerizable monomer including the acid group include a tri- or tetra-functional photopolymerizable monomer including the acid group (component obtained by introducing a carboxylic group to pentaerythritol tri- and tetra-acrylate [PETA] skeleton (acid value=80 to 120 mgKOH/g)), and a penta- to hexa-functional photopolymerizable monomer including the acid group (component obtained by introducing a carboxylic acid group to dipentaerythritol penta- and hexa-acrylate [DPHA] skeleton (acid value=25 to 70 mgKOH/g)).

The tri- or higher functional photopolymerizable monomer including the acid group may be used in combination with the difunctional photopolymerizable monomer including the acid group, if necessary.

As the photopolymerizable monomer including the acid group, at least one kind selected from the group consisting of di- or higher functional photopolymerizable monomer including carboxyl group and a carboxylic acid anhydride thereof is preferable. Accordingly, the perspiration resistance of the cured film increases.

The di- or higher functional photopolymerizable monomer including a carboxyl group is not particularly limited and can be suitably selected from well-known compounds.

For example, as the di- or higher functional photopolymerizable monomer including a carboxyl group, ARONIX (registered trademark) TO-2349 (manufactured by Toagosei Co., Ltd.), ARONIX M-520 (manufactured by Toagosei Co., Ltd.), or ARONIX M-510 (manufactured by Toagosei Co., Ltd.) can be preferably used.

The photopolymerizable monomer including the acid group is also preferably a polymerizable compound including an acid group disclosed in paragraphs 0025 to 0030 of JP2004-239942A. The content of this publication is incorporated in this specification.

A weight-average molecular weight (Mw) of the photopolymerizable monomer which can be included in the photosensitive resin composition of the disclosure is preferably 200 to 3,000, more preferably 250 to 2,600, and even more preferably 280 to 2,200.

In a case where the photosensitive resin composition of the disclosure includes the photopolymerizable monomer, a molecular weight of the photopolymerizable monomer having the minimum molecular weight, among all of the photopolymerizable monomers included in the photosensitive resin composition is preferably equal to or greater than 250, more preferably equal to or greater than 280, and even more preferably equal to or greater than 300.

In a case where the photosensitive resin composition of the disclosure includes the photopolymerizable monomer, a percentage of the content of the photopolymerizable monomer having a molecular weight equal to or smaller than 300, among all of the photopolymerizable monomers included in the photosensitive resin composition, with respect to all of the polymerizable compounds included in the photosensitive resin composition, is preferably equal to or smaller than 30% by mass, more preferably equal to or smaller than 25% by mass, and even more preferably equal to or smaller than 20% by mass.

The content of the photopolymerizable monomer in the photosensitive resin composition of the disclosure is preferably 1% by mass to 70% by mass, more preferably 10% by mass to 70% by mass, even more preferably 20% by mass to 60% by mass, and particularly preferably 20% by mass to 50% by mass with respect to the amount of solid contents of the photosensitive resin composition.

In addition, in a case where the photosensitive resin composition of the disclosure includes a difunctional photopolymerizable monomer and a tri- or higher functional photopolymerizable monomer, the content of the difunctional photopolymerizable monomer is preferably 10% by mass to 90% by mass, more preferably 20% by mass to 85% by mass, and even more preferably 30% by mass to 80% by mass, with respect to all of the photopolymerizable monomers included in the photosensitive resin composition.

In this case, the content of the tri- or higher functional photopolymerizable monomer is preferably 10% by mass to 90% by mass, more preferably 15% by mass to 80% by mass, and even more preferably 20% by mass to 70% by mass, with respect to all of the photopolymerizable monomers included in the photosensitive resin composition.

In this case, the content of the di- or higher functional photopolymerizable monomer is preferably equal to or greater than 40% by mass and smaller than 100% by mass, more preferably 40% by mass to 90% by mass, even more preferably 50% by mass to 80% by mass, and particularly preferably 50% by mass to 70% by mass, with respect to a total content of the difunctional photopolymerizable monomer and the tri- or higher functional photopolymerizable monomer.

In a case where the photosensitive resin composition of the disclosure includes the di- or higher functional photopolymerizable monomer, the photosensitive resin composition may further include a monofunctional photopolymerizable monomer.

However, in a case where the photosensitive resin composition of the disclosure includes the di- or higher functional photopolymerizable monomer, the di- or higher functional photopolymerizable monomer is preferably a main component in the photopolymerizable monomer included in the photosensitive resin composition.

Specifically, in a case where the photosensitive resin composition of the disclosure includes the di- or higher functional photopolymerizable monomer, the content of the di- or higher functional photopolymerizable monomer is preferably 60% by mass to 100% by mass, more preferably 80% by mass to 100% by mass, particularly preferably 90% by mass to 100% by mass with respect to a total content of the photopolymerizable monomer included in the photosensitive resin composition.

In a case where the photosensitive resin composition of the disclosure includes the photopolymerizable monomer including the acid group (preferably, di- or higher functional photopolymerizable monomer including a carboxyl group or a carboxylic acid anhydride thereof), the content of the photopolymerizable monomer including the acid group is preferably 1% by mass to 50% by mass, more preferably 1% by mass to 20% by mass, and even more preferably 1% by mass to 10% by mass, with respect to the amount of solid contents of the photosensitive resin composition.

<Photopolymerization Initiator>

The photosensitive resin composition of the disclosure includes at least one kind of a photopolymerization initiator.

The photopolymerization initiator is not particularly limited and a well-known photopolymerization initiator can be used.

Examples of the photopolymerization initiator include a photopolymerization initiator including an oxime ester structure (hereinafter, also referred to as an “oxime-based photopolymerization initiator”), a photopolymerization initiator including an α-aminoalkylphenone structure (hereinafter, also referred to as an “α-aminoalkylphenone-based photopolymerization initiator”), a photopolymerization initiator including an α-hydroxyalkylphenone structure (hereinafter, also referred to as an “α-hydroxyalkylphenone-based photopolymerization initiator”), a photopolymerization initiator including an acylphosphine oxide structure (hereinafter, also referred to as an “acylphosphine oxide-based photopolymerization initiator”), and a photopolymerization initiator including an N-phenylglycine structure (hereinafter, also referred to as an “N-phenylglycine-based photopolymerization initiator”).

The photopolymerization initiator preferably includes at least one kind selected from the group consisting of the oxime-based photopolymerization initiator, the α-aminoalkylphenone-based photopolymerization initiator, the α-hydroxyalkylphenone-based photopolymerization initiator, and the N-phenylglycine-based photopolymerization initiator, and more preferably includes at least one kind selected from the group consisting of the oxime-based photopolymerization initiator, the α-aminoalkylphenone-based photopolymerization initiator, and the N-phenylglycine-based photopolymerization initiator.

In addition, as the photopolymerization initiator, for example, polymerization initiators disclosed in paragraphs 0031 to 0042 of JP2011-095716A and paragraphs 0064 to 0081 of JP2015-014783A may be used.

Examples of a commercially available product of the photopolymerization initiator include 1,2-octanedione, 1-[4-(phenylthio)-, 2-(O-benzoyloxime)] (product name: IRGACURE (registered trademark) OXE-01, manufactured by BASF Japan Ltd.), ethan, 1-[9-ethyl-6-(2-methylbenzoyl)-9H-carbazol-3-yl]-, 1-(0-acetyloxime) (product name: IRGACURE OXE-02, manufactured by BASF Japan Ltd.), 2-(dimethylamino)-2-[(4-methylphenyl) methyl]-1-[4-(4-morpholinyl) phenyl]-1-butanone (product name: IRGACURE 379EG, manufactured by BASF Japan Ltd.), 2-methyl-1-(4-methylthiophenyl)-2-morpholinopropan-1-one (product name: IRGACURE 907, manufactured by BASF Japan Ltd.), 2-hydroxy-1-{4-[4-(2-hydroxy-2-methyl-propionyl)-benzyl] phenyl}-2-methyl-propan-1-one (product name: IRGACURE 127, manufactured by BASF Japan Ltd.), 2-benzyl-2-dimethylamino-1-(4-morpholinophenyl)-butanone-1 (product name: IRGACURE 369, manufactured by BASF Japan Ltd.), 2-hydroxy-2-methyl-1-phenyl-propan-1-one (product name: IRGACURE 1173, manufactured by BASF Japan Ltd.), 1-hydroxy-cyclohexyl-phenyl-ketone (product name: IRGACURE 184, manufactured by BASF Japan Ltd.), 2,2-dimethoxy-1,2-diphenylethan-1-one (product name: IRGACURE 651, manufactured by BASF Japan Ltd.), and a product name of an oxime ester type (product name: Lunar 6, manufactured by DKSH Management Ltd.).

A content of the photopolymerization initiator in the photosensitive resin composition of the disclosure is not particularly limited.

The content of the photopolymerization initiator is preferably equal to or greater than 0.1% by mass, more preferably equal to or greater than 0.5% by mass, and even more preferably equal to or greater than 1.0% by mass with respect to the amount of solid contents of the photosensitive resin composition.

In addition, the content of the photopolymerization initiator is preferably equal to or smaller than 10% by mass and more preferably equal to or smaller than 5% by mass, with respect to the amount of solid contents of the photosensitive resin composition.

<Other Polymers>

The photosensitive resin composition of the disclosure may include polymers other than the specific polymer.

The kind of the other polymer is not particularly limited, and a well-known polymer can be used.

Examples of the other polymer include a (meth)acryl resin, a polysiloxane resin, a polystyrene resin, and a polyimide resin.

The other polymer can be used in combination of two or more kinds thereof.

The other polymer preferably includes an acid group, from a viewpoint of developability.

Examples of the acid group include a carboxyl group, a phosphoric acid group, and a sulfonic acid group, and a carboxyl group is preferable.

The other polymer preferably includes a structural unit including a carboxyl group (preferably, structural unit derived from (meth)acrylic acid). In this case, a percentage of the structural unit including a carboxyl group in the other polymer is preferably 1% by mol to 50% by mol and more preferably 5% by mol to 35% by mol, with respect to a total content of all of the structural units included in the other polymer.

The other polymer is preferably a (meth)acryl resin.

Here, the (meth)acryl resin indicates a resin including at least one of a structural unit derived from a (meth)acrylic acid and a structural unit derived from (meth)acrylic acid ester.

A total percentage of the structural unit derived from a (meth)acrylic acid and the structural unit derived from (meth)acrylic acid ester in the (meth)acryl resin is preferably equal to or greater than 30% by mol and more preferably equal to or greater than 50% by mol, with respect to a total content of all of the structural units included in the (meth)acryl resin.

The (meth)acryl resin preferably includes the structural unit derived from (meth)acrylic acid. In this case, a percentage of the structural unit derived from (meth)acrylic acid in the (meth)acryl resin is preferably 1% by mol to 50% by mol and more preferably 5% by mol to 35% by mol, with respect to a total content of all of the structural units included in the (meth)acryl resin.

A weight-average molecular weight (Mw) of the other polymer (preferably, (meth)acryl resin. the same applies hereinafter) is preferably 5,000 to 100,000 and more preferably 10,000 to 50,000.

An acid value of the other polymer is preferably equal to or greater than 60 mgKOH/g.

As the other polymer a carboxyl group-containing acryl resin having an acid value equal to or greater than 60 mgKOH/g is preferably used, among the polymers disclosed in a paragraph 0025 of JP2011-95716A, and paragraphs 0033 to 0052 of JP2010-237589A.

The acid value of the other polymer is preferably 60 mgKOH/g to 200 mgKOH/g, more preferably 60 mgKOH/g to 150 mgKOH/g, and even more preferably 60 mgKOH/g to 110 mgKOH/g.

A content of the other polymer is preferably 10% by mass to 95% by mass, more preferably 20% by mass to 80% by mass, and particularly preferably 30% by mass to 70% by mass, with respect to the solid contents of the photosensitive resin composition.

In the photosensitive resin composition of the disclosure, a mass ratio of the total amount of the photopolymerizable monomer with respect to the total amount of the polymer (total amount of photopolymerizable monomer/total amount of the polymer) is preferably 0.20 to 0.90, more preferably 0.30 to 0.80, and particularly preferably 0.40 to 0.80.

In a case where the photosensitive resin composition of the disclosure includes the other polymer, the total amount of the polymer is a total amount of the specific polymer and the other polymer.

In the photosensitive resin composition of the disclosure, a total amount of the total amount of the polymer and the total amount of photopolymerizable monomer is preferably equal to or greater than 60% by mass and more preferably equal to or greater than 70% by mass, with respect to the solid contents of the photosensitive resin composition.

<Thermal Crosslinking Compound>

The photosensitive resin composition of the disclosure may include at least one kind of a thermal crosslinking compound, from a viewpoint of further improving perspiration resistance of the cured film.

The thermal crosslinking compound is preferably a compound including two or more of thermal reactive groups in one molecule. The compound including two or more thermal reactive groups in one molecule is reacted with heat to form a crosslinked structure.

In a case where the photosensitive resin composition of the disclosure includes the thermal crosslinking compound, the photosensitive resin composition does not only have photosensitivity (that is, photocuring properties), but also has thermosetting properties.

In a case where the photosensitive resin composition of the disclosure has both photocuring properties and thermosetting properties, a cured film having excellent hardness can be formed by photocuring, and the hardness of the cured film can be further improved and the perspiration resistance of the cured film can be further decreased by heat curing after forming the cured film.

The thermal reactive group of the thermal crosslinking compound is preferably at least one kind selected from the group consisting of an isocyanate group, a ketene group, a blocked isocyanate group, and a blocked ketene group, from a viewpoint of further decreasing the perspiration resistance of the cured film.

That is, the thermal crosslinking compound particularly preferably includes two or more thermal reactive groups which are at least one kind selected from the group consisting of an isocyanate group, a ketene group, a blocked isocyanate group, and a blocked ketene group, in one molecule.

The thermal crosslinking compound may include a hydrophilic group in one molecule.

Since the thermal crosslinking compound includes a hydrophilic group in one molecule, developability is improved.

The thermal crosslinking compound including a hydrophilic group in one molecule is not particularly limited and well-known compounds can be used.

A synthesis method of the thermal crosslinking compound including a hydrophilic group in one molecule is not particularly limited, either.

As the hydrophilic group of the thermal crosslinking compound including a hydrophilic group in one molecule, a nonionic hydrophilic group or a cationic hydrophilic group is preferable.

The nonionic hydrophilic group is not particularly limited, and a group having a structure in which ethylene oxide or propylene oxide is added to a hydroxyl group of any alcohol of methanol, ethanol, butanol, ethylene glycol, and diethylene glycol is used, for example.

The thermal crosslinking compound may be a compound which reacts with acid due to heat.

The thermal crosslinking compound which is a compound reacting with acid due to heat, reacts with an acid group (for example, acid group in the (meth)acryl resin as the other polymer) present in a system due to heating. Accordingly, polarity in the system decreases, and therefore, hydrophilicity decreases.

As the thermal crosslinking compound which is a compound reacting with acid due to heat, a compound which includes a group temporarily inactivated due to a blocking agent (for example, a blocked isocyanate group, a blocked ketene group, and the like) as a thermal reactive group and which can react with acid by dissociating a blocking agent-derived group at a predetermined dissociation temperature is preferable.

The thermal crosslinking compound which is a compound reacting with acid due to heat is preferably a compound having higher reactivity with acid after heating at a temperature higher than 25° C., compared to reactivity with acid at 25° C. is preferable.

The thermal crosslinking compound which is a compound reacting with acid due to heat is even more preferably a compound including a blocked isocyanate group (hereinafter, “blocked isocyanate compound”) or a compound including a blocked ketene group (hereinafter, “blocked ketene compound”), and particularly preferably a blocked isocyanate compound.

According to this aspect, in a case of a protective film which protects the electrode and the like (for example, protective film for a touch panel) is formed with the photosensitive resin composition, corrosion of the electrode due to the thermal crosslinking compound is prevented.

(Blocked Isocyanate Compound)

The blocked isocyanate compound is preferably a compound having a structure which protects (masks) an isocyanate group of an isocyanate compound (that is, compound including an isocyanate group) with a blocking agent.

The blocked isocyanate compound preferably includes a hydrophilic group in one molecule. The preferred aspect of the hydrophilic group is as described above.

A dissociation temperature of the blocked isocyanate compound is preferably 100° C. to 160° C. and more preferably 130° C. to 150° C.

Here, the dissociation temperature of the blocked isocyanate compound is a “temperature of an endothermic peak accompanied with a deprotection reaction of blocked isocyanate, in a case where the measurement is performed by differential scanning calorimetry (DSC) analysis using a differential scanning calorimetry (manufactured by Seiko Instruments Inc., DSC 6200)”.

Examples of the blocking agent for forming the blocked isocyanate compound (for example, blocked isocyanate compound having a dissociation temperature of 100° C. to 160° C.) include a pyrazole based compound (3,5-dimethylpyrazole, 3-methylpyrazole, 4-bromo-3,5-dimethylpyrazole, or 4-nitro-3,5-dimethylpyrazole), an active methylene based compound (malonic acid diester (dimethyl malonate, diethyl malonate, di n-butyl malonate, di 2-ethylhexyl malonate)), a triazole based compound (1,2,4-triazole), an oxime-based compound (compound having a structure represented by —C(═N—OH)— in one molecule; for example, formaldoxime, acetoaldoxime, acetoxime, methyl ethyl ketoxime, or cyclohexanone oxime).

Among these, from a viewpoint of storage stability, an oxime based compound and a pyrazole based compound are preferable, and an oxime based compound is more preferable.

From a viewpoint of improving toughness of the cured film and adhesiveness of a substrate, the blocked isocyanate compound preferably has an isocyanurate structure.

The blocked isocyanate compound having an isocyanurate structure is, for example, synthesized by isocyanurating hexamethylene diisocyanate.

Among the blocked isocyanate compound having an isocyanurate structure, the compound having an oxime structure using the oxime-based compound as the blocking agent is preferable, compared to a compound not having an oxime structure, because the dissociation temperature is easily controlled to be in a preferred range and a development residue is easily decreased.

As the blocked isocyanate compound, a blocked isocyanate compound disclosed in paragraphs 0074 to 0085 of JP2006-208824A may be used, and the content of this publication is incorporated in the specification.

Specific examples of the blocked isocyanate compound include the following compounds. However, the blocked isocyanate compound is not limited to the following compounds. In the structure of the following compounds, “*” shows a bonding site.

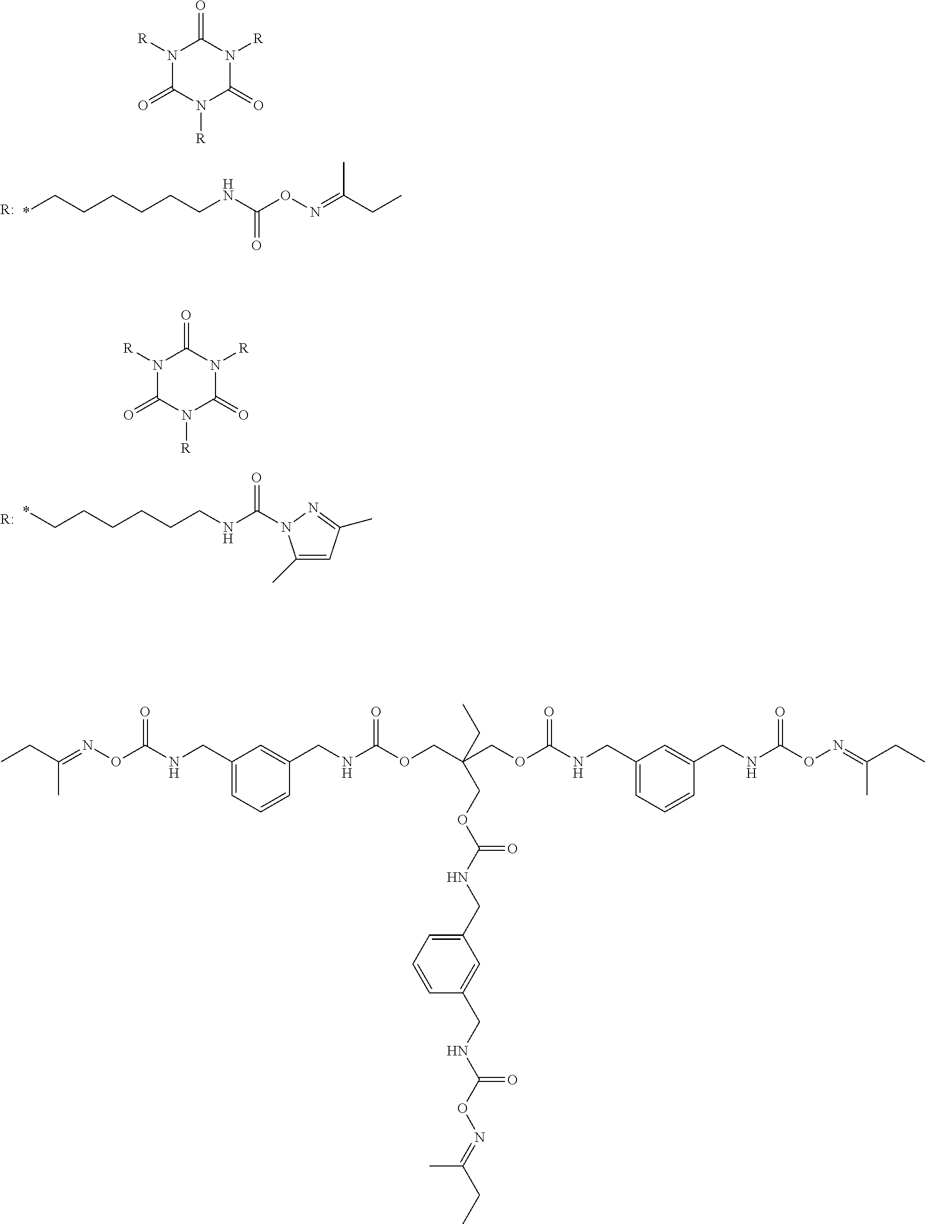

As the blocked isocyanate compound, a commercially available product may be used. Examples of the commercially available product of the blocked isocyanate compound include TAKENATE (registered trademark) B870N (manufactured by Mitsui Chemicals, Inc.) which is a methyl ethyl ketone oxime blocked body of isophorone diisocyanate, and DURANATE (registered trademark) MF-K60B, TPA-B80E, and X3071.04 (all manufactured by Asahi Kasei Corporation) which is a hexamethylene diisocyanate-based blocked isocyanate compound.

(Blocked Ketene Compound)

Examples of the blocked ketene compound include a compound having a structure in which a ketene group of a ketene compound (that is, a compound including a ketene group) is protected with a blocking agent, and a compound in which a ketene group is generated due to light or heat.

Specific examples of the blocking agent for forming the blocked ketene compound are the same as the specific examples of the blocking agent for forming the blocked isocyanate compound.

More specific examples of the blocked ketene compound include a compound having a naphthoquinone diazide structure, and a compound having a Meldrum's acid structure.

Examples of the blocked ketene compound include naphthoquinone diazide sulfonic acid ester of 4-{4-[1,1-bis (4-hydroxyphenyl) ethyl]-α,α-dimethylbenzyl}phenol, and naphthoquinone diazide sulfonic acid ester of 2,3,4-trihydroxybenzophenone.

As the blocked ketene compound, a commercially available product may be used.

Examples of the commercially available product of the blocked ketene compound include TAS-200 manufactured by Toyo Gosei Co., Ltd. which is naphthoquinone diazide sulfonic acid ester of 4-{4-[1,1-bis (4-hydroxyphenyl) ethyl]-α,α-dimethylbenzyl}phenol. In addition, naphthoquinone diazide sulfonic acid ester of 2,3,4-trihydroxybenzophenone can also be purchased.

In a case where the photosensitive resin composition of the disclosure includes the thermal crosslinking compound (for example, the blocked isocyanate compound or the blocked ketene compound), a content of the thermal crosslinking compound is preferably 1% by mass to 50% by mass, more preferably 5% by mass to 40% by mass, even more preferably 10% by mass to 40% by mass, and particularly preferably 10% by mass to 30% by mass, with respect to the amount of solid contents of the photosensitive resin composition.

<Solvent>

The photosensitive resin composition of the disclosure may include at least one kind of a solvent, from a viewpoint of forming a photosensitive layer by coating.

As the solvent, a solvent normally used can be used without particular limitations.

The solvent is preferably an organic solvent.

Examples of the organic solvent include methyl ethyl ketone, propylene glycol monomethyl ether, propylene glycol monomethyl ether acetate (another name: 1-methoxy-2-propyl acetate), diethylene glycol ethyl methyl ether, cyclohexanone, methyl isobutyl ketone, ethyl lactate, methyl lactate, caprolactam, n-propanol, and 2-propanol. The photosensitive resin composition of the disclosure may include a mixed solvent which is a mixture of these compounds.

As the solvent, a mixed solvent of methyl ethyl ketone and propylene glycol monomethyl ether acetate, or a mixed solvent of diethylene glycol ethyl methyl ether and propylene glycol monomethyl ether acetate is preferable.

In a case where the photosensitive resin composition of the disclosure includes the solvent, a content of solid contents of the photosensitive resin composition of the disclosure is preferably 5% by mass to 80% by mass, more preferably 5% by mass to 40% by mass, and particularly preferably 5% by mass to 30% by mass with respect to a total amount of the photosensitive resin composition.

In a case where the photosensitive resin composition of the disclosure includes the solvent, a viscosity (25° C.) of the photosensitive resin composition is preferably 1 mPa·s to 50 mPa·s, more preferably 2 mPa·s to 40 mPa·s, and particularly preferably 3 mPa·s to 30 mPa·s, from a viewpoint of coating properties.

The viscosity is, for example, measured using VISCOMETER TV-22 (manufactured by TOKI SANGYO CO. LTD.).

In a case where the photosensitive resin composition of the disclosure includes the solvent, a surface tension (25° C.) of the photosensitive resin composition is preferably 5 mN/m to 100 mN/m, more preferably 10 mN/m to 80 mN/m, and particularly preferably 15 mN/m to 40 mN/m, from a viewpoint of coating properties.

The surface tension is, for example, measured using Automatic Surface Tensiometer CBVP-Z (manufactured by Kyow a Interface Science Co., Ltd.).

As the solvent, a solvent disclosed in paragraphs 0054 and 0055 of US2005/282073A1 can also be used, and the content of this specification is incorporated in the present specification.

In addition, as the solvent, an organic solvent (high-boiling-point solvent) having a boiling point of 180° C. to 250° C. can also be used, if necessary.

<Surfactant>

The photosensitive resin composition of the disclosure may include at least one kind of the surfactant.

As the surfactant, surfactants disclosed in a paragraph 0017 of JP4502784B and paragraphs 0060 to 0071 of JP2009-237362A, a well-known fluorine surfactant, and the like can be used, for example.

As the surfactant, a fluorine surfactant is preferable.

As a commercially available product of the fluorine surfactant, MEGAFACE (registered trademark) F551 (manufactured by DIC Corporation) is used.

In a case where the photosensitive resin composition of the disclosure includes the surfactant, a content of the surfactant is preferably 0.01% by mass to 3% by mass, more preferably 0.05% by mass to 1% by mass, and even more preferably 0.1% by mass to 0.8% by mass with respect to the amount of solid contents of the photosensitive resin composition.

<Polymerization Inhibitor>

The photosensitive resin composition of the disclosure may include at least one kind of the polymerization inhibitor.

As the polymerization inhibitor, a thermal polymerization inhibitor (also referred to as a polymerization inhibitor) disclosed in a paragraph [0018] of JP4502784B can be used.

Among these, phenothiazine, phenoxazine, or 4-methoxyphenol can be suitably used.

In a case where the photosensitive resin composition of the disclosure includes the polymerization inhibitor, a content of the polymerization inhibitor is preferably 0.01% by mass to 3% by mass, more preferably 0.01% by mass to 1% by mass, and even more preferably 0.01% by mass to 0.8% by mass with respect to the amount of solid contents of the photosensitive resin composition.

<Other Components>

The photosensitive resin composition of the disclosure may include a component other than the components described above.

Examples of the other components include a thermal polymerization inhibitor disclosed in a paragraph 0018 of JP4502784B, and other additives disclosed in paragraphs 0058 to 0071 of JP2000-310706.

The photosensitive resin composition of the disclosure may include at least one kind of particles (for example, metal oxide particles) as the other component, in order to adjust a refractive index or light transmittance.

The metal of the metal oxide particles also includes semimetal such as B, Si, Ge, As, Sb, or Te. From a viewpoint of transparency of the cured film, an average primary particle diameter of the particles (for example, metal oxide particles) is preferably 1 to 200 nm and more preferably 3 to 80 nm. The average primary particle diameter is calculated by measuring particle diameters of 200 random particles using an optical microscope and averaging the measured result. In a case where the shape of the particle is a spherical shape, the longest side is set as the particle diameter.

The content of the particles is preferably 0% by mass to 35% by mass, more preferably 0% by mass to 10% by mass, even more preferably 0% by mass to 5% by mass, still more preferably 0% by mass to 1% by mass, and particularly preferably 0% by mass (that is, the photosensitive resin composition includes no particles), with respect to the amount of solid contents of the photosensitive resin composition.

In addition, the photosensitive resin composition of the disclosure may include a small amount of colorant (pigment, dye, and the like) as the other component, but it is preferable that a colorant is not substantially included, from a viewpoint of transparency.

Specifically, a content of the colorant in the photosensitive resin composition of the disclosure is preferably smaller than 1% by mass and more preferably smaller than 0.1% by mass with respect to the amount of solid contents of the photosensitive resin composition.

[Transfer Film]

A transfer film of the disclosure includes a temporary support, and a photosensitive layer including solid contents of the photosensitive resin composition of the disclosure.

The transfer film of the disclosure is suitable for forming a cured film on a substrate. In a case of forming the cured film on the substrate using the transfer film of the disclosure, the cured film is formed on the substrate, by laminating the transfer film of the disclosure to the substrate to be formed as the cured film, so as to transfer a photosensitive layer of the transfer film of the disclosure, and performing processes of exposure and development with respect to the photosensitive layer transferred onto the substrate.

According to the transfer film of the disclosure, the effect of forming the cured film having excellent perspiration resistance is exhibited, in the same manner as the effect of the photosensitive resin composition of the disclosure.

As described above, according to the transfer film of the disclosure, even in a case where the laminating condition of a high temperature (for example, equal to or higher than 120° C.) is applied at a stage of laminating the transfer film in a case of forming the cured film, the effect of preventing the occurrence of the development residue due to thermal fogging is exhibited.

In addition, as described above, the transfer film of the disclosure is particularly suitable for forming a protective film for a touch panel as the cured film.

The photosensitive layer of the transfer film includes solid contents of the photosensitive resin composition of the disclosure.

That is, in a case where the photosensitive resin composition of the disclosure includes the solvent, the photosensitive layer of the transfer film at least includes components (that is, solid contents) other than the solvent of the photosensitive resin composition. In this case, the photosensitive layer may further include a solvent. As a case where the photosensitive layer includes the solvent, a case where the solvent remains in the photosensitive layer even after drying, in a case of forming the photosensitive layer by applying and drying the photosensitive resin composition including the solvent, is used, for example.

In addition, in a case where the photosensitive resin composition of the disclosure does not include the solvent, the photosensitive layer of the transfer film includes all components of the photosensitive resin composition.

Hereinafter, each component which can be included in the transfer film of the disclosure will be described.

<Temporary Support>

The transfer film of the disclosure includes a temporary support.

The temporary support is preferably a film and more preferably a resin film.

As the temporary support, a film which has flexibility and does not generate significant deformation, shrinkage, or stretching under the pressure or under pressure and heating can be used.

Examples of such a film include a polyethylene terephthalate film, a cellulose triacetate film, a polystyrene film, a polyimide film, and a polycarbonate film.

Among these, a biaxial stretching polyethylene terephthalate film is particularly preferable.

A thickness of the temporary support is not particularly limited, and is, for example, 5 μm to 200 μm. The thickness of the temporary support is particularly preferably 10 μm to 150 μm, from viewpoints of ease of handling and general-purpose properties.

<Photosensitive Layer>

The transfer film of the disclosure includes a photosensitive layer including solid contents of the photosensitive resin composition of the disclosure.

The photosensitive layer has photosensitivity (that is, photocuring properties), and may further have thermosetting properties. Examples of means for applying thermosetting properties to the photosensitive layer include means for causing the thermal crosslinking compound described above to be included in the photosensitive resin composition of the disclosure. In a case where the photosensitive layer has both photocuring properties and thermosetting properties, hardness of the cured film can be further improved and the perspiration resistance of the cured film can be improved.

The photosensitive layer preferably further has alkali solubility (for example, solubility with respect to weak alkali aqueous solution). Examples of means for applying alkali solubility to the photosensitive layer include means for causing a polymer including an acid group to be included in the photosensitive resin composition of the disclosure as the other polymer described above.

In addition, the photosensitive layer is preferably a transparent layer.

Examples of means for setting the photosensitive layer as the transparent layer include means for setting the content of the colorant in the photosensitive resin composition of the disclosure to be smaller than 1% by mass.

A thickness of the photosensitive layer is preferably equal to or smaller than 20 μm, more preferably equal to or smaller than 15 μm, and particularly preferably equal to or smaller than 12 μm.

In a case where the thickness of the photosensitive layer is equal to or smaller than 20 μm, it is advantageous from viewpoints of thinning of the entire transfer film, improvement of transmittance of the photosensitive layer or the cured film to be obtained, and the prevention of the photosensitive layer or the cured film from being stained into yellow.

In general, in a case where the thickness of the photosensitive layer is equal to or smaller than 20 μm, the perspiration resistance of the cured film may be deteriorated. However, in the photosensitive layer of the transfer film of the disclosure, even in a case where the thickness of the photosensitive layer is equal to or smaller than 20 μm, a deterioration in perspiration resistance of the cured film due to a decrease in thickness can be prevented.

The thickness of the photosensitive layer is preferably equal to or greater than 1 μm, more preferably equal to or greater than 2 μm, and particularly preferably equal to or greater than 3 μm, from a viewpoint of manufacturing suitability.

A refractive index of the photosensitive layer is preferably 1.47 to 1.56, more preferably 1.50 to 1.53, even more preferably 1.50 to 1.52, and particularly preferably 1.51 to 1.52.

In the specification, the “refractive index” indicates a refractive index at a wavelength of 550 nm.

The “refractive index” in the specification means a value measured with visible light at a wavelength of 550 nm at a temperature of 23° C. by ellipsometry, unless otherwise noted.

A forming method of the photosensitive layer is not particularly limited.

As an example of the forming method of the photosensitive layer, a method of forming the photosensitive layer by applying and, if necessary, drying the photosensitive resin composition of the disclosure having an aspect of including the solvent, on the temporary support is used.

As the coating method, a well-known method can be used, and examples thereof include a printing method, a spraying method, a roll coating method, a bar coating method, a curtain coating method, a spin coating method, and a die coating method (that is, slit coating method), and a die coating method is preferable.

As the drying method, a well-known method such as natural drying, heating drying, and drying under reduced pressure can be applied alone or in combination of plural thereof.

<Protective Film>

The transfer film of the disclosure may further include a protective film on a side of the photosensitive layer opposite to the temporary support.

In a case where the transfer film of the disclosure includes a refractive index adjusting layer which will be described later on a side of the photosensitive layer opposite to the temporary support, the protective film is preferably disposed on a side of the refractive index adjusting layer opposite to the temporary support.

Examples of the protective film include a polyethylene terephthalate film, a polypropylene film, a polystyrene film, and a polycarbonate film.

As the protective film, a component disclosed in paragraphs 0083 to 0087 and 0093 of JP2006-259138A may be used, for example.

<Thermoplastic Resin Layer>

The transfer film of the disclosure may further include a thermoplastic resin layer between a temporary support and a photosensitive layer.

In a case where the transfer film includes the thermoplastic resin layer and the transfer film is transferred to a substrate to form a laminate, air bubbles are hardly generated on each component of the laminate. In a case where this laminate is used in an image display apparatus, image unevenness is hardly generated and excellent display properties are obtained.

The thermoplastic resin layer preferably has alkali solubility.

The thermoplastic resin layer functions as a cushion material which absorbs ruggedness of the surface of the substrate at the time of transfer.

The ruggedness of the surface of the substrate includes an image, an electrode, a wiring, and the like which are formed in advance. The thermoplastic resin layer preferably has properties capable of being deformed in accordance with ruggedness.

The thermoplastic resin layer preferably includes an organic polymer substance disclosed in JP1993-072724A (JP-H5-072724A), and more preferably includes an organic polymer substance having a softening point approximately equal to or lower than 80° C. by a Vicat method (specifically, polymer softening point measurement method using a American Society for Testing and Materials ASTMD 1235).

A thickness of the thermoplastic resin layer is preferably 3 μm to 30 μm, more preferably 4 μm to 25 μm, and even more preferably 5 μm to 20 μm.

In a case where the thickness of the thermoplastic resin layer is equal to or greater than 3 μm, followability with respect to the ruggedness of the surface of the substrate is improved, and accordingly, the ruggedness of the surface of the substrate can be effectively absorbed.

In a case where the thickness of the thermoplastic resin layer is equal to or smaller than 30 μm, process suitability is further improved. For example, burden of the drying (solvent removal) in a case of applying and forming the thermoplastic resin layer on the temporary support is further reduced, and the development time of the thermoplastic resin layer after the transfer is shortened.

The thermoplastic resin layer can be formed by applying and, if necessary, drying a composition for forming a thermoplastic resin layer including a solvent and a thermoplastic organic polymer on the temporary support.

Specific examples of the coating and drying method are respectively the same as the specific examples of the coating and drying in a case of forming the photosensitive layer.

The solvent is not particularly limited, as long as a polymer component forming the thermoplastic resin layer is dissolved, and examples thereof include organic solvents (for example, methyl ethyl ketone, cyclohexanone, propylene glycol monomethyl ether acetate, n-propanol, and 2-propanol).

A viscosity of the thermoplastic resin layer measured at 100° C. is preferably 1,000 to 10,000 Pa·s. In addition, the viscosity of the thermoplastic resin layer measured at 100° C. is preferably lower than the viscosity of the photosensitive layer measured at 100° C.

<Interlayer>

The transfer film of the disclosure may further include an interlayer between the temporary support and the photosensitive layer.

In a case where the transfer film of the disclosure includes the thermoplastic resin layer, the interlayer is preferably disposed between the thermoplastic resin layer and the photosensitive layer.

As the component of the interlayer, a resin which is a mixture including polyvinyl alcohol, polyvinyl pyrrolidone, cellulose, or at least two kinds thereof.

In addition, as the interlayer, a component disclosed in JP1993-072724A (JP-H5-072724A) as a “separation layer” can also be referred to.

In a case of manufacturing the transfer film of the aspect including the thermoplastic resin layer, the interlayer, and the photosensitive layer on the temporary support in this order, the interlayer can be, for example, formed by applying and, if necessary, drying a composition for forming an interlayer including a solvent which does not dissolve the thermoplastic resin layer, and the resin as the component of the interlayer. Specific examples of the coating and drying method are respectively the same as the specific examples of the coating and drying in a case of forming the photosensitive layer.

In this case, for example, first, the composition for forming a thermoplastic resin layer is applied and dried on the temporary support to form the thermoplastic resin layer. Next, the composition for forming an interlayer is applied and dried on this thermoplastic resin layer to form the interlayer. After that, the photosensitive resin composition of the disclosure of the aspect including the organic solvent is applied and dried on the interlayer to form the photosensitive layer. The organic solvent in this case is preferably an organic solvent which does not dissolve the interlayer.

<Refractive Index Adjusting Layer>

The transfer film of the disclosure may further include a refractive index adjusting layer on a side of the photosensitive layer opposite to a side where the temporary support is present (for example, see specific example of the transfer film which will be described later).

According to the transfer film of the aspect including the refractive index adjusting layer, in a case of forming a protective film for a touch panel by transferring the refractive index adjusting layer and the photosensitive layer of the transfer film to a substrate for a touch panel including a transparent electrode pattern, the transparent electrode pattern is more hardly recognized (that is, concealing properties of the transparent electrode pattern are further improved). A phenomenon that the transparent electrode pattern is recognized, is generally referred to as “see-through”.

Regarding the phenomenon that the transparent electrode pattern is recognized, and the concealing properties of the transparent electrode pattern, JP2014-010814A and JP2014-108541A can be suitably referred to.

The refractive index adjusting layer is preferably disposed to be adjacent to the photosensitive layer.

The refractive index of the refractive index adjusting layer is preferably higher than the refractive index of the photosensitive layer.

The refractive index of the refractive index adjusting layer is preferably equal to or greater than 1.50, more preferably equal to or greater than 1.55, and particularly preferably equal to or greater than 1.60.

An upper limit of the refractive index of the refractive index adjusting layer is not particularly limited, and is preferably equal to or smaller than 2.10, more preferably equal to or smaller than 1.85, even more preferably equal to or smaller than 1.78, and particularly preferably equal to or smaller than 1.74.

The refractive index adjusting layer may have photocuring properties (that is, photosensitivity), may have thermosetting properties, or may have both photocuring properties and thermosetting properties.

From a viewpoint of forming the cured film having excellent hardness by the photocuring after the transfer, the refractive index adjusting layer preferably has photocuring properties.

From viewpoints of further improving hardness of the cured film and further improving perspiration resistance of the cured film by the heat curing, the refractive index adjusting layer preferably has thermosetting properties.

The refractive index adjusting layer preferably has thermosetting properties and photocuring properties.

The refractive index adjusting layer preferably has alkali solubility (for example, solubility with respect to weak alkali aqueous solution).

In addition, the refractive index adjusting layer is preferably a transparent layer.

The aspect in which the refractive index adjusting layer has photosensitivity, has an advantage, from a viewpoint of collectively patterning the photosensitive layer and the refractive index adjusting layer transferred onto the substrate by photolithography at one time, after the transferring.

A film thickness of the refractive index adjusting layer is preferably equal to or smaller than 500 nm, more preferably equal to or smaller than 110 nm, and particularly preferably equal to or smaller than 100 nm.

In addition, the film thickness of the refractive index adjusting layer is preferably equal to or greater than 20 nm, more preferably equal to or greater than 50 nm, even more preferably equal to or greater than 55 nm, and particularly preferably equal to or greater than 60 nm.

The film thickness of the refractive index adjusting layer is even more preferably 50 nm to 100 nm, still more preferably 55 nm to 100 nm, and particularly preferably 60 nm to 100 nm.

The refractive index of the refractive index adjusting layer is preferably adjusted in accordance with the refractive index of the transparent electrode pattern.

In a case where the refractive index of the transparent electrode pattern is 1.8 to 2.0, as in a case of the transparent electrode pattern formed of ITO, the refractive index of the refractive index adjusting layer is preferably equal to or greater than 1.60. An upper limit of the refractive index of the refractive index adjusting layer in this case is not particularly limited, and is preferably equal to or smaller than 2.1, more preferably equal to or smaller than 1.85, even more preferably equal to or smaller than 1.78, and particularly preferably equal to or smaller than 1.74.

In addition, in a case where the refractive index of the transparent electrode pattern is greater than 2.0, as in a case of the transparent electrode pattern formed of indium zinc oxide (IZO), for example, the refractive index of the refractive index adjusting layer is preferably 1.70 to 1.85.

A method of controlling the refractive index of the refractive index adjusting layer is not particularly limited, and examples thereof include a method using a resin having a predetermined refractive index alone, a method using a resin and metal oxide particles and metal particles, and a method using a composite of metal salt and a resin.

The refractive index adjusting layer preferably includes at least one kind selected from the group consisting of inorganic particles having a refractive index equal to or greater than 1.50 (more preferably equal to or greater than 1.55, and particularly preferably equal to or greater than 1.60), a resin having a refractive index equal to or greater than 1.50 (more preferably equal to or greater than 1.55, and particularly preferably equal to or greater than 1.60), and a polymerizable monomer having a refractive index equal to or greater than 1.50 (more preferably equal to or greater than 1.55, and particularly preferably equal to or greater than 1.60).

According to this aspect, the refractive index of the refractive index adjusting layer is easily adjusted to be equal to or greater than 1.50 (more preferably equal to or greater than 1.55, and particularly preferably equal to or greater than 1.60).

In addition, the refractive index adjusting layer preferably includes a binder polymer a polymerizable monomer, and particles.

Regarding the components of the refractive index adjusting layer, components of a curable transparent resin layer disclosed in paragraphs 0019 to 0040 and 0144 to 0150 of JP2014-108541A, and components of a transparent layer disclosed in paragraphs 0024 to 0035 and 0110 to 0112 of JP2014-010814A, and components of a composition including ammonium salt disclosed in paragraphs 0034 to 0056 of W02016/009980 can be referred to.

In addition, the refractive index adjusting layer preferably includes at least one kind of a metal oxide suppressing agent.

In a case where the refractive index adjusting layer includes the metal oxide suppressing agent, surface treatment can be performed with respect to a member (for example, conductive member formed on a substrate) in a direct contact with the refractive index adjusting layer, in a case of transferring the refractive index adjusting layer onto the substrate (that is, a target to be transferred). This surface treatment applies a metal oxide suppressing function (protection properties) with respect to the member in a direct contact with the refractive index adjusting layer.

The metal oxide suppressing agent is preferably a compound having an “aromatic ring including nitrogen atoms”. The compound having an “aromatic ring including nitrogen atoms” may include a substituent.

The “aromatic ring including nitrogen atoms” is preferably an imidazole ring, a triazole ring, a tetrazole ring, a thiazole ring, a thiadiazole ring, or a fused ring of any one thereof and another aromatic ring, and more preferably an imidazole ring, a triazole ring, a tetrazole ring, or a fused ring of any one thereof and another aromatic ring.

The “another aromatic ring” forming the fused ring may be a homocyclic ring or a heterocyclic ring, and is preferably a homocyclic ring, more preferably a benzene ring or a naphthalene ring, and even more preferably a benzene ring.

As the metal oxide suppressing agent, imidazole, benzimidazole, tetrazole, 5-amino-1H-tetrazole, mercaptothiadiazole, 1,2,4-triazole, or benzotriazole is preferable, and imidazole, benzimidazole, 5-amino-1H-tetrazole, 1,2,4-triazole, or benzotriazole is more preferable.

As the metal oxide suppressing agent, a commercially available product may be used, and as the commercially available product, BT 120 manufactured by Johoku Chemical Co., Ltd. including benzotriazole can be preferably used, for example.

In a case where the refractive index adjusting layer includes the metal oxide suppressing agent, a content of the metal oxide suppressing agent is preferably 0.1% by mass to 20% by mass, more preferably 0.5% by mass to 10% by mass, and even more preferably 1% by mass to 5% by mass with respect to the amount of solid contents of the refractive index adjusting layer.

The refractive index adjusting layer may include a component other than the component described above.

The other component which can be included in the refractive index adjusting layer is the same as the other component which can be included in the photosensitive resin composition of the disclosure.

The refractive index adjusting layer preferably includes a surfactant as the other component.

A forming method of the refractive index adjusting layer is not particularly limited.

As an example of the forming method of the refractive index adjusting layer, a method of forming the layer of high refractive index by applying and, if necessary, drying a composition for forming refractive index adjusting layer of the aspect including an aqueous solvent, on the photosensitive layer formed on the temporary support is used.

Specific examples of the coating and drying method are respectively the same as the specific examples of the coating and drying in a case of forming the photosensitive layer.

The composition for forming the refractive index adjusting layer can include each component of the refractive index adjusting layer described above.

The composition for forming the refractive index adjusting layer, for example, includes a binder polymer a polymerizable monomer, particles, and an aqueous solvent.

In addition, as the composition for forming the refractive index adjusting layer, a composition including ammonium salt disclosed in paragraphs 0034 to 0056 of WO2016/009980 is also preferable.

<Specific Example of Transfer Film>

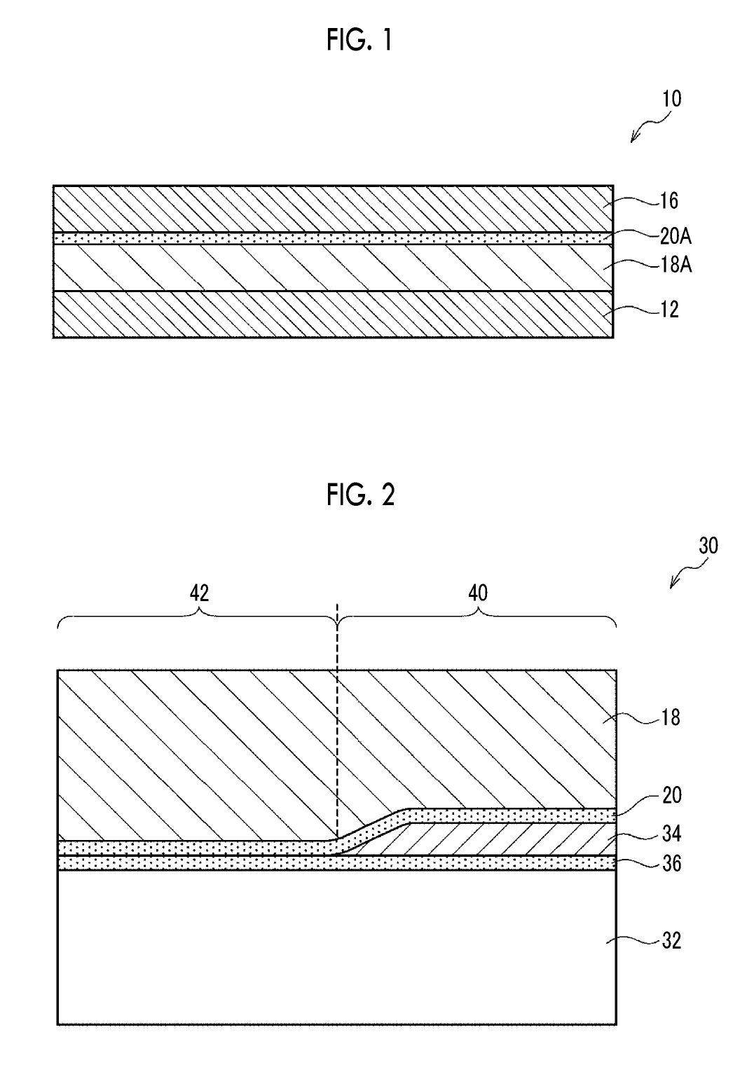

FIG. 1 is a schematic cross sectional view showing a transfer film 10 which is a specific example of the transfer film of the disclosure.

As shown in FIG. 1, the transfer film 10 has a laminated structure of protective film 16/refractive index adjusting layer 20A/photosensitive layer 18A/temporary support 12 (that is, laminated structure in which a temporary support 12, a photosensitive layer 18A, a refractive index adjusting layer 20A, and a protective film 16 are laminated in this order).

However, the transfer film of the disclosure is not limited to the transfer film 10, and the refractive index adjusting layer 20A and the protective film 16 may be omitted, for example. In addition, at least one of the thermoplastic resin layer or the interlayer described above may be included between the temporary support 12 and the photosensitive layer 18A.

The photosensitive layer 18A is a layer including solid contents of the photosensitive resin composition of the disclosure.

The refractive index adjusting layer 20A is a layer disposed on a side of the photosensitive layer 18A opposite to the side where the temporary support 12 is present, and a layer having a refractive index at a wavelength of 550 nm equal to or greater than 1.50.

The transfer film 10 is a negative type material (negative type film).

A manufacturing method of the transfer film 10 is not particularly limited.

The manufacturing method of the transfer film 10, for example, includes a step of forming the photosensitive layer 18A on the temporary support 12, a step of forming the refractive index adjusting layer 20A on the photosensitive layer 18A, and a step of forming the protective film 16 on the refractive index adjusting layer 20A in this order.

The manufacturing method of the transfer film 10 may include a step of volatilizing ammonia disclosed in a paragraph 0056 of WO2016/009980, between the step of forming the refractive index adjusting layer 20A and the step of forming the protective film 16.

[Protective Film for Touch Panel and Touch Panel]

The protective film for a touch panel of the disclosure is a cured product of solid contents of the photosensitive resin composition of the disclosure described above.

The touch panel of the disclosure includes the protective film for a touch panel of the disclosure.

Since the protective film for a touch panel of the disclosure is a cured product of solid contents of the photosensitive resin composition of the disclosure described above, the perspiration resistance is excellent.

A preferred aspect of the touch panel of the disclosure is an aspect including a substrate for a touch panel having a structure in which the electrode and the like (that is, at least one of the electrode for a touch panel or the wiring for a touch panel is disposed on the substrate, and the protective film for a touch panel of the disclosure which covers at least a part of the electrode and the like directly or through other layers.

As the substrate, a glass substrate or a resin substrate is preferable.

In addition, the substrate is preferably a transparent substrate and more preferably a transparent resin substrate. The meaning of the transparency is as described above.

A refractive index of the substrate is preferably 1.50 to 1.52.

As the glass substrate, tempered glass such as GORILLA GLASS (registered trademark) manufactured by Corning Incorporated can be used.

As the resin substrate, at least one of a component without optical strains or a component having high transparency is preferably used, and a substrate formed of a resin such as polyethylene terephthalate (PET), polyethylene naphthalate (PEN), polycarbonate (PC), triacetyl cellulose (TAC), polyimide (PI), polybenzoxazole (PBO), or cycloolefin polymer (COP) is used, for example.

As a material of the transparent substrate, a material disclosed in JP2010-086684A, JP2010-152809A, and JP2010-257492A is preferably used.

As the electrode for a touch panel, a transparent electrode pattern disposed at least in an image display region of the touch panel is used. The electrode for a touch panel may extend from the image display region to a frame portion of the touch panel.

As the wiring for a touch panel, a leading wiring (lead-out wiring) disposed on the frame portion of the touch panel is used, for example.

As a preferred aspect of the substrate for a touch panel and the touch panel, an aspect in which the transparent electrode pattern and the leading wiring are electrically connected to each other by laminating a part of the leading wiring on a portion of the transparent electrode pattern extending to the frame portion of the touch panel, is suitable.

As a material of the transparent electrode pattern, a metal oxide film of indium tin oxide (ITO) and indium zinc oxide (IZO) is preferable.

As a material of the leading wiring, metal is preferable. Examples of the metal which is the material of the leading wiring include gold, silver, copper, molybdenum, aluminum, titanium, chromium, zinc, and manganese, and alloy formed of two or more kinds of these metal elements. As the material of the leading wiring, copper, molybdenum, aluminum, or titanium is preferable, copper is particularly preferable.

the protective film for a touch panel of the disclosure is provided so as to cover the electrode and the like directly or through other layers, in order to protect the electrode and the like (that is, at least one of the electrode for a touch panel and the wiring for a touch panel).

The preferred range of a thickness of the protective film for a touch panel is the same as the preferred range of a thickness of the photosensitive layer described above.

The protective film for a touch panel of the disclosure may include an opening.

The opening of the protective film for a touch panel of the disclosure can be formed by dissolving an unexposed portion of the photosensitive layer with a developer.

In this case, in a case where the protective film for a touch panel is formed under the laminating condition at a high temperature using the transfer film, the development residue of the opening of the protective film for a touch panel is prevented.

The touch panel may further include a first refractive index adjusting layer between the electrode and the like and the protective film for a touch panel (for example, see first specific example of the touch panel which will be described later).

The preferred aspect of the first refractive index adjusting layer is the same as the preferred aspect of the refractive index adjusting layer included in the transfer film. The first refractive index adjusting layer may be formed by applying and drying a composition for forming the first refractive index adjusting layer, or may be formed by transferring the refractive index adjusting layer of the transfer film including first refractive index adjusting layer.

The touch panel of the aspect including the first refractive index adjusting layer is preferably formed by transferring the photosensitive layer and the refractive index adjusting layer of the transfer film by using the transfer film of the disclosure of the aspect including the refractive index adjusting layer. In this case, the protective film for a touch panel is formed of the photosensitive layer of the transfer film, and the first refractive index adjusting layer is formed of the refractive index adjusting layer of the transfer film.

In addition, the touch panel or the substrate for a touch panel may include a second refractive index adjusting layer between the substrate and the electrode and the like (for example, see, first specific example of the touch panel which will be described later).

The preferred aspect of the second refractive index adjusting layer is the same as the preferred aspect of the refractive index adjusting layer included in the transfer film.

The aspect in which the touch panel of the disclosure includes the first refractive index adjusting layer (more preferably, aspect of including the first refractive index adjusting layer and the second refractive index adjusting layer) has an advantage in which the electrode and the like is hardly recognized (that is, so-called see-through is prevented).

Regarding the structure of the touch panel, a structure of a capacitive input device disclosed in JP2014-010814A or JP2014-108541A may be referred to.

<First Specific Example of Touch Panel>

FIG. 2 is a schematic cross sectional view of a touch panel 30 which is the first specific example of the touch panel of the disclosure. More specifically, FIG. 2 is a schematic cross sectional view of an image display region of the touch panel 30.

As shown in FIG. 2, the touch panel 30 has a structure in which a substrate 32, a second refractive index adjusting layer 36, a transparent electrode pattern 34 as the electrode for a touch panel, a first refractive index adjusting layer 20, and a protective film 18 for a touch panel are disposed in this order.

In the touch panel 30, the protective film 18 for a touch panel and the first refractive index adjusting layer 20 cover the entire transparent electrode pattern 34. However, the touch panel of the disclosure is not limited to this aspect. The protective film 18 for a touch panel and the first refractive index adjusting layer 20 may cover at least a portion of the transparent electrode pattern 34.

In addition, the second refractive index adjusting layer 36 and the first refractive index adjusting layer 20 are preferably respectively continuously coated over a first region 40 in which the transparent electrode pattern 34 is present and a second region 42 in which the transparent electrode pattern 34 is not present directly or through another layer. Accordingly, the transparent electrode pattern 34 is more hardly recognized.

The second refractive index adjusting layer 36 and the first refractive index adjusting layer 20 are preferably coated directly over both of the first region 40 and the second region 42, rather than the coating through the other layer. Examples of the “other layer” include an insulating layer and an electrode pattern other than the transparent electrode pattern 34.

The first refractive index adjusting layer 20 is laminated over both of the first region 40 and the second region 42. The first refractive index adjusting layer 20 is adjacent to the second refractive index adjusting layer 36 and is also adjacent to the transparent electrode pattern 34.

In a case where the shape of the end portion of the transparent electrode pattern 34 at a portion in contact with the second refractive index adjusting layer 36 is a tapered shape as shown in FIG. 2, the first refractive index adjusting layer 20 is preferably laminated along the tapered shape (that is, at the same tilt as the taper angle).

As the transparent electrode pattern 34, the ITO transparent electrode pattern is suitable.

The transparent electrode pattern 34 can be, for example, formed by the following method.

A thin film for an electrode (for example, ITO film) is formed on the substrate 32 on which the second refractive index adjusting layer 36 is formed by sputtering. By applying a photosensitive resist for etching or transferring a photosensitive film for etching onto the thin film for an electrode, an etching protective layer is formed. Then, this etching protective layer is patterned in a desired pattern shape by exposure and development. Next, a portion of the thin film for an electrode which is not covered with the patterned etching protective layer is removed by etching. Accordingly, the thin film for an electrode is set to have a pattern having a desired shape (that is, transparent electrode pattern 34). Then, the patterned etching protective layer is removed by a peeling solution.

The first refractive index adjusting layer 20 and the protective film 18 for a touch panel are, for example, formed on the substrate 32 (that is, substrate for a touch panel) on which the second refractive index adjusting layer 36 and the transparent electrode pattern 34 are provided in order, as described below.

First, the transfer film 10 (that is, transfer film 10 having a laminated structure of protective film 16/refractive index adjusting layer 20A/photosensitive layer 18A/temporary support 12) shown in FIG. 1 is prepared.

Next, the protective film 16 is removed from the transfer film 10.

Then, the transfer film 10, from which the protective film 16 is removed, is laminated on the substrate 32 (that is, substrate for a touch panel) on which the second refractive index adjusting layer 36 and the transparent electrode pattern 34 are provided in order. The laminating is performed in a direction in which the refractive index adjusting layer 20A of the transfer film 10, from which the protective film 16 is removed, and the transparent electrode pattern 34 are in contact with each other. By this laminating, a laminate having a laminated structure of temporary support 12/photosensitive layer 18A/refractive index adjusting layer 20A/transparent electrode pattern 34/second refractive index adjusting layer 36/substrate 32 is obtained.

Next, the temporary support 12 is removed from the laminate.

Then, by performing the pattern exposure with respect to the laminate, from which the temporary support 12 is removed, the photosensitive layer 18A and the refractive index adjusting layer 20A are cured in a pattern shape. The curing of the photosensitive layer 18A and the refractive index adjusting layer 20A in a pattern shape may be respectively individually performed by individual pattern exposure, but the curing is preferably performed at the same time by the pattern exposure at one time.

Next, by removing the unexposed portion (that is, uncured portion) of the photosensitive layer 18A and the refractive index adjusting layer 20A by the development, the protective film 18 for a touch panel which is a patterned cured product of the photosensitive layer 18A (not shown regarding the pattern shape), and the first refractive index adjusting layer 20 which is a patterned cured product of the refractive index adjusting layer 20A (not shown regarding the pattern shape) are respectively obtained. The development of the photosensitive layer 18A and the refractive index adjusting layer 20A after the pattern exposure may be respectively individually performed by individual development, but the development is preferably performed at the same time by the development at one time.

The preferred aspects of the laminating, the pattern exposure, and the development will be described later.

Regarding the structure of the touch panel, a structure of a capacitive input device disclosed in JP2014-010814A or JP2014-108541A may be referred to.

<Second Specific Example of Touch Panel>

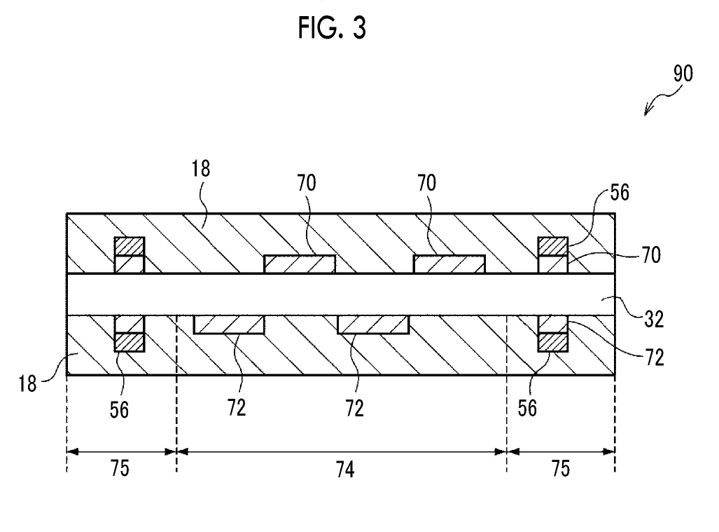

FIG. 3 is a schematic cross sectional view of a touch panel 90 which is a second specific example of the touch panel of the disclosure.

As shown in FIG. 3, the touch panel 90 includes an image display region 74 and an image non-display region 75 (that is, frame portion).

As shown in FIG. 3, the touch panel 90 includes the electrode for a touch panel on both surfaces of the substrate 32. Specifically, the touch panel 90 includes a first transparent electrode pattern 70 on one surface of the substrate 32 and includes a second transparent electrode pattern 72 on the other surface thereof.

In the touch panel 90, a leading wiring 56 is connected to the first transparent electrode pattern 70 and the second transparent electrode pattern 72, respectively. The leading wiring 56 is, for example, a copper wiring.

In the touch panel 90, the protective film 18 for a touch panel is formed on one surface of the substrate 32 so as to cover the first transparent electrode pattern 70 and the leading wiring 56, and the protective film 18 for a touch panel is formed on the other surface of the substrate 32 so as to cover the second transparent electrode pattern 72 and the leading wiring 56.

The first refractive index adjusting layer and the second refractive index adjusting layer of the first specific example may be provided on the one surface and the other surface of the substrate 32, respectively.

[Manufacturing Method of Touch Panel]

The method of manufacturing the touch panel of the disclosure is not particularly limited, and the following manufacturing method is preferable.

The preferred manufacturing method of the touch panel of the disclosure includes a step of preparing a substrate for a touch panel having a structure in which the electrode and the like (that is, at least one of the electrode for a touch panel and the wiring for a touch panel) are disposed on a substrate (hereinafter, also referred to as a “preparation step”), a step of forming a photosensitive layer on a surface of the substrate for a touch panel on a side where the electrode and the like are disposed, using the photosensitive resin composition of the disclosure or the transfer film of the disclosure (hereinafter, also referred to as a “photosensitive layer forming step”), a step of performing pattern exposure with respect to the photosensitive layer formed on the surface of the substrate for a touch panel (hereinafter, also referred to as a “pattern exposure step”), and a step of developing the pattern-exposed photosensitive layer to obtain a protective film for a touch panel which protects at least a portion of the electrode and the like (hereinafter, also referred to as a “development step”).

According to the preferred manufacturing method, a touch panel including the protective film for a touch panel having excellent perspiration resistance can be manufactured.

In addition, in the preferred manufacturing method, even in a case where the photosensitive layer is formed under the laminating condition at a high temperature using the transfer film of the disclosure, the occurrence of the development residue is prevented in the unexposed portion of the photosensitive layer after the development.

Hereinafter, each step of the preferred manufacturing method will be described.

<Preparation Step>

The preparation step is a step for convenience, and is a step of preparing a substrate for a touch panel having a structure in which the electrode and the like (that is, at least one of the electrode for a touch panel and the wiring for a touch panel) are disposed on a substrate.

The preparation step may be a step of only simply preparing the substrate for a touch panel manufactured in advance, or may be a step of manufacturing the substrate for a touch panel.

The preferred aspect of the substrate for a touch panel is as described above.

<Photosensitive Layer Forming Step>

The photosensitive layer forming step is a step of forming a photosensitive layer on a surface of the substrate for a touch panel on a side where the electrode and the like are disposed, using the photosensitive resin composition of the disclosure or the transfer film of the disclosure.

Hereinafter, in the photosensitive layer forming step, the aspect using the transfer film of the disclosure will be described.

In this aspect, the photosensitive layer is formed on the surface by laminating the transfer film of the disclosure on the surface of the substrate for a touch panel on a side on which the electrode and the like are disposed, and transferring the photosensitive layer of the transfer film of the disclosure on the surface.

The laminating (transfer of the photosensitive layer) can be performed using a well-known laminator such as a vacuum laminator or an auto-cut laminator.

As the laminating condition, a general condition can be applied.

A laminating temperature is preferably 80° C. to 150° C., more preferably 90° C. to 150° C., and particularly preferably 100° C. to 150° C.

As described above, in the aspect using the transfer film of the disclosure, even in a case where the laminating temperature is a high temperature (for example, 120° C. to 150° C.), the occurrence of the development residue due to thermal fogging is prevented.

In a case of using a laminator including a rubber roller, the laminating temperature indicates a temperature of the rubber roller.

A temperature of the substrate at the time of laminating is not particularly limited. The temperature of the substrate at the time of laminating is 10° C. to 150° C., preferably 20° C. to 150° C., and more preferably 30° C. to 150° C. In a case of using a resin substrate as the substrate, the temperature of the substrate at the time of laminating is preferably 10° C. to 80° C., more preferably 20° C. to 60° C., and particularly preferably 30° C. to 50° C.

In addition, linear pressure at the time of laminating is preferably 0.5 N/cm to 20 N/cm, more preferably 1 N/cm to 10 N/cm, and particularly preferably 1 N/cm to 5 N/cm.

Further, a transportation speed (laminating speed) at the time of laminating is preferably 0.5 m/min to 5 m/min and more preferably 1.5 m/min to 3 m/min.

In a case of using the transfer film having a laminated structure of the protective film/photosensitive layer/interlayer/thermoplastic resin layer/temporary support, first, the protective film is peeled off from the transfer film to expose the photosensitive layer, the transfer film and the substrate for a touch panel are bonded to each other so that the exposed photosensitive layer and the surface of the substrate for a touch panel on a side on which the electrode and the like are disposed are in contact with each other, and heating and pressurizing are performed. Accordingly, the photosensitive layer of the transfer film is transferred onto the surface of the substrate for a touch panel on a side on which the electrode and the like are disposed, and a laminate having a laminated structure of temporary support/thermoplastic resin layer/interlayer/photosensitive layer/electrode and the like/substrate is formed. In this laminated structure, the portion of “electrode and the like/substrate” is the substrate for a touch panel.

After that, the temporary support is peeled off from the laminate, if necessary. However, the pattern exposure which will be described later can be also performed, by leaving the temporary support.

As an example of the method of transferring the photosensitive layer of the transfer film on the substrate for a touch panel and performing pattern exposure and development, a description disclosed in paragraphs 0035 to 0051 of JP2006-023696A can also be referred to.

Next, the aspect using the photosensitive resin composition of the disclosure without using the transfer film of the disclosure in the photosensitive layer forming step will be described.

As a suitable example of this aspect, the photosensitive resin composition of the disclosure of the aspect including the solvent is applied and dried on the surface of the substrate for a touch panel on a side on which the electrode and the like are disposed, to form the photosensitive layer on the surface.

Specific examples of the coating and drying method are respectively the same as the specific examples of the coating and drying in a case of forming the photosensitive layer on the temporary support. The heat treatment (so-called pre-baking) may be performed with respect to the photosensitive layer after the drying and before the exposure, if necessary.

<Pattern Exposure Step>

The pattern exposure step is a step of performing the pattern exposure with respect to the photosensitive layer formed on the substrate for a touch panel.

Here, the pattern exposure indicates exposure of the aspect of performing the exposure in a pattern shape, that is, the aspect in which an exposed portion and an unexposed portion are present.

The exposed portion of the photosensitive layer on the substrate for a touch panel in the pattern exposure is cured and finally becomes the cured film.

Meanwhile, the unexposed portion of the photosensitive layer on the substrate for a touch panel in the pattern exposure is not cured, and is removed (dissolved) with a developer in the subsequent development step. With the unexposed portion, the opening of the cured film can be formed after the development step.

The pattern exposure may be exposure through a mask or may be digital exposure using a laser or the like.

As a light source of the pattern exposure, a light source can be suitably selected, as long as it can emit light at a wavelength region (for example, 365 nm or 405 nm) at which the photosensitive layer can be cured. Examples of the light source include various lasers, an LED, an ultrahigh pressure mercury lamp, a high pressure mercury vapor lamp, and a metal halide lamp. An exposure intensity is, for example, 5 mJ/cm² to 200 mJ/cm², and is preferably 10 mJ/cm² to 200 mJ/cm².

In a case where the photosensitive layer is formed on the substrate using the transfer film, the pattern exposure may be performed after peeling the temporary support, or the temporary support may be peeled off after performing the exposure before peeling off the temporary support.

In addition, in the exposure step, the heat treatment (so-called post exposure bake (PEB)) may be performed with respect to the photosensitive layer after the pattern exposure and before the development.

<Development Step>

The development step is a step of obtaining the protective film for a touch panel which protects at least a portion of the electrode and the like, by developing the pattern-exposed photosensitive layer (that is, by dissolving the unexposed portion of the pattern exposure with a developer).

A developer used in the development is not particularly limited, and a well-known developer such as a developer disclosed in JP1993-072724A (JP-H5-072724A) can be used.

As the developer, an alkali aqueous solution is preferably used.

Examples of the alkali compound which can be included in the alkali aqueous solution include sodium hydroxide, potassium hydroxide, sodium carbonate, potassium carbonate, sodium hydrogen carbonate, potassium hydrogencarbonate, tetramethyl ammonium hydroxide, tetraethyl ammonium hydroxide, tetrapropyl ammonium hydroxide, tetrabutylammonium hydroxide, and choline (2-hydroxyethyltrimethylammonium hydroxide).

The pH of the alkali aqueous solution at 25° C. is preferably 8 to 13, more preferably 9 to 12, and particularly preferably 10 to 12.

A content of the alkali compound in the alkali aqueous solution is preferably 0.1% by mass to 5% by mass and more preferably 0.1% by mass to 3% by mass with respect to a total amount of the alkali aqueous solution.

The developer may include an organic solvent having miscibility with water.

Examples of the organic solvent include methanol, ethanol, 2-propanol, 1-propanol, butanol, diacetone alcohol, ethylene glycol monomethyl ether, ethylene glycol monoethyl ether, ethylene glycol mono-n-butyl ether, benzyl alcohol, acetone, methyl ethyl ketone, cyclohexanone, ϵ-caprolactone, γ-butyrolactone, dimethylformamide, dimethylacetamide, hexamethylphosphoramide, ethyl lactate, methyl lactate, ϵ-caprolactam, and N-methylpyrrolidone. A concentration of the organic solvent is preferably 0.1% by mass to 30% by mass.

The developer may include a well-known surfactant. A concentration of the surfactant is preferably 0.01% by mass to 10% by mass.

A liquid temperature of the developer is preferably 20° C. to 40° C.

Examples of the development method include methods such as puddle development, shower development, shower and spin development, and dip development.

In a case of the shower development, the unexposed portion of the photosensitive layer is removed by spraying the developer to the photosensitive layer after the pattern exposure as a shower. In a case of using the transfer film including at least one of the photosensitive layer, the thermoplastic resin layer, and the interlayer, after the transfer of these layers onto the substrate and before the development of the photosensitive layer, an alkali solution having a low solubility of the photosensitive layer may be sprayed as a shower, and at least one of the thermoplastic resin layer or the interlayer (both layers, in a case where both layers are present) may be removed in advance.

In addition, after the development, the development residue is preferably removed by spraying a cleaning agent with a shower and rubbing with a brush or the like.

A liquid temperature of the developer is preferably 20° C. to 40° C.

The development step may include a stage of performing the development, and a stage of performing the heat treatment (hereinafter, also referred to as “post baking”) with respect to the cured film obtained by the development.

In a case where the substrate is a resin substrate, a temperature of the post baking is preferably 100° C. to 160° C. and more preferably 130° C. to 160° C.

A resistance value of the transparent electrode pattern can also be adjusted by this post baking.

In addition, in a case where the photosensitive layer includes a carboxyl group-containing (meth)acrylic resin, at least a part of the carboxyl group-containing (meth)acrylic resin can be changed to carboxylic acid anhydride by the post baking. Accordingly, the cured film having excellent perspiration resistance is obtained.

In addition, the development step may include a stage of performing the development, and a stage of exposing the cured film obtained by the development (hereinafter, also referred to as “post exposure”).

In a case where the development step includes a stage of performing the post exposure and a stage of performing the post baking, the post exposure and the post baking are preferably performed in this order.

Regarding the pattern exposure and the development, a description disclosed in paragraphs 0035 to 0051 of JP2006-023696A can be referred to, for example.

The preferred manufacturing method of the touch panel of the disclosure may include a step other than the steps described above. As the other step, a step (for example, washing step or the like) which may be provided in a normal photolithography step can be applied without any particular limitations.

[Image Display Apparatus]

The image display apparatus of the disclosure includes the touch panel of the disclosure described above (for example, touch panels of the first and second specific examples).

As the structure of the image display apparatus of the disclosure, a liquid crystal display apparatus having a structure in which the touch panel of the disclosure is overlapped on a well-known liquid crystal display element is preferable.

As the structure of the image display apparatus including the touch panel, for example, a structure disclosed in “The latest Touch Panel Technology” (published 6 Jul. 2009, Techno Times), “Technologies and Developments of Touch Panels” supervised by Yuji Mitani, CMC Publishing CO., LTD. (2004, 12), FPD International 2009 Forum T-11 lecture text book, Cypress Semiconductor Corporation application note AN 2292 can be applied.

### EXAMPLES

Hereinafter, examples of the disclosure will be described, but the disclosure is not limited to the following examples.

Hereinafter, “part” and “%” respectively mean “parts by mass” and “% by mass”.

### Examples 1 to 26 and Comparative Examples 1 to 5

21 Preparation of Photosensitive Resin Composition (Materials A-1 to A-31)>

As the photosensitive resin composition for forming the photosensitive layer of the transfer film, materials A-1 to A-31 having the composition shown in Tables 2 to 6 which will be described later were prepared. Specifically, the materials were mixed and stirred as the composition shown in Tables 2 to 6 to obtain a solvent solution, and filtering was performed with a filter made of polytetrafluoroethylene having a hole diameter of 0.3 μm, and accordingly, the materials A-1 to A-31 were prepared.

In Tables 2 to 6, the “other polymer” means a polymer other than the specific polymer (that is, polymer including the structural unit having the carboxylic acid anhydride structure).

(Preparation of Solution Having Concentration of Solid Contents of Polymer C-1 of 35.0% by Mass)

A solution having a concentration of solid contents of a polymer C-1 of 35.0% by mass (polymer including structural unit having the carboxylic acid anhydride structure) used in the preparation of the material A-13 was prepared as follows.

Methacrylic acid (22.3 g: amount which is 11.2% by mass in all of the monomer components), methyl methacrylate (41.8 g: amount which is 20.9% by mass in all of the monomer components), styrene (99.9 g: corresponding to 50.0% by mass in all of the monomer components), V-601 (11.17 g) (manufactured by Wako Pure Chemical Industries, Ltd.), 4-methoxyphenol (0.01 g), and propylene glycol monomethyl ether acetate (15.0 g) were mixed with each other, and a dropping solution 1 was obtained.

Itaconic acid anhydride (35.8 g: corresponding to 17.9% by mass in all of the monomer components), propylene glycol monomethyl ether acetate (236.3 g), and 4-methoxyphenol (0.01 g) were mixed with each other, and a dropping solution 2 was obtained.

Propylene glycol monomethyl ether acetate (119.9 g) was put into a three-neck flask and heated to 85° C. ±1° C. in a nitrogen atmosphere. The dropwise addition of the dropping solution 1 was started with respect to the heated propylene glycol monomethyl ether acetate, and the dropwise addition of the dropping solution 2 was started after 15 minutes from the start of the dropwise addition of the dropping solution 1. Here, the dropping solution 1 was added dropwise for 2 hours, and the dropping solution 2 was added dropwise for 2 hours and 15 minutes.

After completing the dropwise addition of the dropping solution 2, the mixture was stirred at 85° C.±1° C. for 1.5 hours, and V-601 (4.50 g) was added and stirred at 85° C.±1° C. for 4 hours. After that, by cooling to room temperature, a solution having a concentration of solid contents of the polymer C-1 (Mw=13,000) of 35.0% by mass was obtained.

(Preparation of Solution Having Concentration of Solid Contents of Polymer D of 36.3% by Mass)

In the preparation of materials A-1 to A-31, as the other polymer, a solution having a concentration of solid contents of polymer D having the following structure of 36.3% by mass was used. In the polymer D, a lower right numerical value of each structural unit represents a content ratio (% by mol) of each structural unit.

The solution having a concentration of solid contents of polymer D of 36.3% by mass was prepared by a polymerization step and an addition step shown below.

Polymerization Step

60 g of propylene glycol monomethyl ether acetate (manufactured by Sanwa Kagaku Sangyo Co., Ltd., product name: PGM-Ac) and 240 g of propylene glycol monomethyl ether (manufactured by Sanwa Kagaku Sangyo Co., Ltd., product name: PGM) were introduced to a flask of 2,000 ml. The obtained liquid was stirred at a stirring speed of 250 rpm and heated to 90° C.

In the preparation of the dropping solution (1), 107.1 g of methacrylic acid (manufactured by Mitsubishi Rayon Co., Ltd., product name: acryl ester M), 5.46 g of methyl methacrylate (manufactured by Mitsubishi Gas Chemical Company, product name: MMA), and 231.42 g of cyclohexyl methacrylate (manufactured by Mitsubishi Gas Chemical Company, product name: CHMA) were mixed with each other and diluted with 60 g of PGM-Ac, and accordingly, the dropping solution (1) was obtained.

In the preparation of the dropping solution (2), 9.637 g of dimethyl 2,2′-azobis (2-methylpropionate) (manufactured by Wako Pure Chemical Industries, Ltd., product name: V-601) and 136.56 g of PGM-Ac were dissolved, and accordingly, the dropping solution (2) was obtained.

The dropping solution (1) and the dropping solution (2) were added dropwise to the flask of 2,000 ml (specifically, flask of 2,000 ml including the liquid heated to 90° C.) for 3 minutes at the same time. Then, the container of the dropping solution (1) was washed with 12 g of PGM-Ac and a washing solution was added dropwise to the flask of 2,000 ml. Then, the container of the dropping solution (2) was washed with 6 g of PGM-Ac and the washing solution was added dropwise to the flask of 2,000 ml. During the dropwise addition, a reaction solution in the flask of 2,000 ml was maintained at 90° C. and stirred at a stirring speed of 250 rpm. In addition, as the postreaction, the reaction solution was stirred at 90° C. for 1 hour.

2.401 g of V-601 was added to the reaction solution after the postreaction, as the first additional addition of the initiator. In addition, the container of V-601 was washed with 6 g of PGM-Ac, and the washing solution was introduced to the reaction solution. After that, the reaction solution was stirred at 90° C. for 1 hour.

Next, 2.401 g of V-601 was added to the reaction solution as the second additional addition of the initiator. In addition, the container of V-601 was washed with 6 g of PGM-Ac, and the washing solution was introduced to the reaction solution. After that, the reaction solution was stirred at 90° C. for 1 hour.

Next, 2.401 g of V-601 was added to the reaction solution as the third additional addition of the initiator. In addition, the container of V-601 was washed with 6 g of PGM-Ac, and the washing solution was introduced to the reaction solution. After that, the reaction solution was stirred at 90° C. for 3 hours.

Addition Step

After stirring at 90° C. for 3 hours, 178.66 g of PGM-Ac was introduced to the reaction solution. Next, 1.8 g of tetraethylammonium bromide (manufactured by Wako Pure Chemical Industries, Ltd.) and 0.8 g of hydroquinone monomethyl ether (manufactured by Wako Pure Chemical Industries, Ltd.) were added to the reaction solution. Each container was washed with 6 g of PGM-Ac, and the washing solution was introduced to the reaction solution. After that, the temperature of the reaction solution was increased to 100° C.

Next, 76.03 g of glycidyl methacrylate (manufactured by NOF CORPORATION, product name: BLEMMER G) was added dropwise to the reaction solution for 1 hour. The container of BLEMMER G was washed with 6 g of PGM-Ac, and the washing solution was introduced to the reaction solution. After that, the reaction solution was stirred at 100° C. for 6 hours as an addition reaction.

Then, the reaction solution was cooled and filtered with a mesh filter (100 meshes) for collecting dust, and 1,158 g of a solution of the polymer D was obtained (concentration of solid contents of 36.3% by mass). Regarding the obtained polymer D, the weight-average molecular weight was 27,000, the number average molecular weight was 15,000, and the acid value was 95 mgKOH/g.

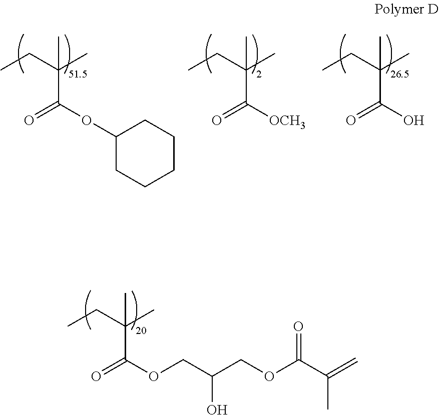

<Manufacturing of Transfer Film>

A coated film was obtained by applying a photosensitive resin composition (specifically, any one of materials A-1 to A-31) onto a polyethylene terephthalate (PET) film having a thickness of 16 μm as the temporary support using a slit-shaped nozzle, and dried at a drying temperature of 100° C., and accordingly, a photosensitive layer was formed. Here, a coating amount of the photosensitive resin composition was adjusted so that a film thickness after drying becomes 8.0 μm.

Next, by pressing a protective film (polyethylene terephthalate (PET) film having a thickness of 16 μm) on the photosensitive layer on the temporary support, a transfer film having a laminated structure of protective film/photosensitive layer/temporary support was obtained.

<Evaluation of Development Residue>

(Manufacturing of Substrate for Touch Panel)

As a substrate for evaluation of the development residue, a substrate for a touch panel having a laminated structure of ITO transparent electrode pattern/refractive index adjusting layer/COP substrate was manufactured. The details are shown below.

First, as the substrate, a cycloolefin resin film having a thickness of 38 μm and a refractive index of 1.53 (hereinafter, also referred to as a “COP substrate”) was prepared. By performing a corona discharge treatment for 3 seconds with respect to this COP substrate under the conditions of an output voltage of 100%, an output of 250W, an electrode length of 240 mm, and a work electrode of 1.5 mm using a wire electrode having a diameter of 1.2 mm, by using a high frequency oscillator, surface modification of the COP substrate was performed.

The coated film was formed on the surface-modified COP substrate by applying the material of the material -C shown in Table 1 using a slit-shaped nozzle, the coated film was irradiated (entire surface exposure) with an ultraviolet light at integral of light of 300 mJ/cm², and the coated film was dried at a drying temperature of 110° C., and accordingly, a refractive index adjusting layer having a refractive index of 1.60 and a film thickness of 80 nm was formed.

By doing so, the COP substrate attached with the refractive index adjusting layer was obtained.

TABLE 1

| Material | Material-C |
|---|---|
| ZrO₂: ZR-010 manufactured by Solar Co., Ltd. | 2.08 |
| Monomer: KAYARAD DPHA (manufactured by Nippon | 0.22 |
| Kayaku Co., Ltd.), mixture of dipentaerythritol | |
| hexa-acrylate and dipentaerythritol penta-acrylate | |
| Urethane monomer: UK oligo UA-32P (manufactured by | 0.14 |
| Shin-Nakamura Chemical Co., Ltd.) non-volatilized amount | |
| 75%, 1-methoxy-2-propyl acetate: 25% | |
| Monomer: Viscoat #802 (manufactured by Osaka Organic | 0.36 |
| Chemical Industry Ltd.), mixture of tripentaerythritol acrylate, | |
| mono- and dipentaerythritol acrylate, and poly | |
| pentaerythritol acrylate | |
| Solution of polymer having the following structure (solid | 1.89 |
| content: 45%, 1-methoxy-2-propyl acetate: 15%, | |
| 1-methoxy-2-propanol: 40%) | |
| Photopolymerization initiator: Irgacure 379 | 0.03 |
| (2-benzyl-2-dimethylamino-1-(4-morpholinophenyl)-butane, | |
| manufactured by BASF Japan Ltd.) | |
| Photopolymerization initiator: KAYACURE-DETX-S | 0.03 |
| (manufactured by Nippon Kayaku Co., Ltd., alkyl | |
| thioxanthone | |
| MEGAFACE F-444 (manufactured by DIC Corporation) | 0.01 |
| 1-methoxy-2-propyl acetate | 38.80 |
| Methyl ethyl ketone | 56.44 |
| Total (parts by mass) | 100.00 |

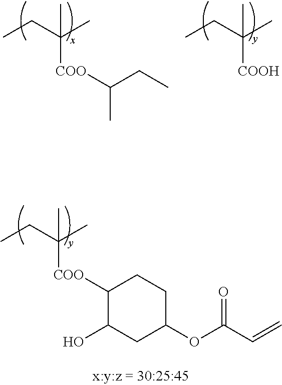

In the polymer having the structure, x, y, and z are number shown with % by mol, and the weight-average molecular weight was 35,000.

An indium tin oxide (ITO) film having a thickness of 40 nm and a refractive index of 1.82 was formed on the refractive index adjusting layer of the COP substrate attached with the refractive index adjusting layer by DC magnetron sputtering, the formed ITO film was patterned by photoetching, and accordingly, an ITO transparent electrode pattern was formed on the refractive index adjusting layer. The formation of the ITO film and the patterning of the ITO film (that is, the formation of the ITO transparent electrode pattern) were performed by the method disclosed in paragraphs 0119 to 0122 of JP2014-010814A.

By doing so, a substrate for a touch panel having a laminated structure of ITO transparent electrode pattern/refractive index adjusting layer/COP substrate was obtained.

(Transfer of Photosensitive Layer Using Transfer Film (Laminating))

The protective film was peeled off from the transfer film described above, the transfer film, from which the protective film was peeled off, was laminated on the substrate for a touch panel, and accordingly, the photosensitive layer of the transfer film was bonded to the surface of the substrate for a touch panel on a side on which the ITO transparent electrode pattern was formed. The laminating conditions were set as conditions with a temperature of the substrate for a touch panel of 40° C., a rubber roller temperature (that is, laminating temperature) of 110° C., linear pressure of 3 N/cm, and a transportation speed of 2 m/min.

Accordingly, a laminate having a laminated structure of temporary support/photosensitive layer/ITO transparent electrode pattern/refractive index adjusting layer/COP substrate was obtained.

(Pattern Exposure and Development)

The photosensitive layer of the laminate was pattern-exposed through the temporary support.

The pattern exposure was performed using a proximity type exposure device including an ultrahigh pressure mercury lamp (manufactured by Hitachi High-Tech Electronics Engineering Co., Ltd.) and an exposure mask, under the condition of an exposure intensity of 100 mJ/cm² (i ray) by setting a distance between an exposure mask surface and the temporary support as 125 μm.

After the pattern exposure, the temporary support was peeled off from the laminate.

Then, the photosensitive layer of the laminate, from which the temporary support was peeled off, was developed by using an aqueous solution having a concentration of sodium carbonate of 2% by mass (liquid temperature of 30° C.) as the developer for 40 seconds. Accordingly, a protective film for a touch panel including an opening (that is, unexposed portion) from which a portion of the ITO transparent electrode pattern was exposed, was obtained.

By doing so, a touch panel having a laminated structure of protective film for a touch panel/ITO transparent electrode pattern/refractive index adjusting layer/COP substrate was obtained.

The protective film for a touch panel obtained as described above was observed with an optical microscope (magnification of 10 times).

Even in a case of any examples and comparative examples, the development residue could not be confirmed in the opening of the protective film for a touch panel.

(Evaluation of Development Residue)

Next, the rubber roller temperature (that is, laminating temperature) at the time of laminating was changed to each temperature of 120° C., 130° C., and 140° C., and the same operation as the operation from the laminating to the development was performed.

The protective film for a touch panel of the touch panel formed at each laminate temperature was observed with the optical microscope (magnification of 10 times), respectively, and the development residue of the opening (that is, unexposed portion) of each protective film for a touch panel was confirmed. The development residue was evaluated based on the following evaluation standard in accordance with the confirmed results.

The results are shown in Tables 2 to 6.

In the following evaluation standards, A or B means that the development residue due to thermal fogging at the time of laminating is prevented.

Evaluation Standards of Development Residue

A: density of development residue of the opening of the protective film for a touch panel was 0 piece/1 cm² (that is, development residue was not observed).

B: density of development residue of the opening of the protective film for a touch panel was equal to or greater than 1 piece/1 cm² and smaller than 3 piece/1 cm².

C: density of development residue of the opening of the protective film for a touch panel was equal to or greater than 3 piece/1 cm².

<Evaluation of Perspiration Resistance of Protective Film for Touch Panel>

(Manufacturing of Sample for Perspiration Resistance Evaluation)

The protective film was peeled off from the transfer film, the transfer film, from which the protective film was peeled off, was laminated on a PET film (manufactured by), on which copper foil was laminated, and accordingly, a photosensitive layer of the transfer film was transferred onto the surface of the copper foil. The laminating conditions were set as conditions with a temperature of the substrate for a touch panel of 40° C., a rubber roller temperature (that is, laminating temperature) of 110° C., linear pressure of 3 N/cm, and a transportation speed of 2 m/min. Here, the copper foil is a film assumed as the leading wiring of the touch panel.

The entire surface of the photosensitive layer of the laminate was exposed through the temporary support. The entire surface exposure was performed using a proximity type exposure device including an ultrahigh pressure mercury lamp (manufactured by Hitachi High-Tech Electronics Engineering Co., Ltd.) under the condition with exposure intensity of 100 mJ/cm2 (i ray).

After the entire surface exposure, the temporary support was peeled off from the laminate.

Next, the photosensitive layer of the laminate, from which the temporary support was peeled off, was developed by using an aqueous solution having a concentration of sodium carbonate of 2% by mass (liquid temperature of 30° C.) as the developer for 40 seconds. After the development, moisture was removed by blowing air, a heating (post baking) process at 145° C. was performed for 30 minutes, and accordingly, a sample for perspiration resistance evaluation having a laminated structure of protective film for a touch panel/copper foil/PET film was obtained.

(Evaluation of Perspiration Resistance)

Acidic artificial perspiration was produced based on JIS standard (JIS L0848 (2004)). 30 μL of the artificial perspiration was added dropwise to the surface of the protective film for a touch panel of the sample for perspiration resistance evaluation, and the artificial perspiration was naturally dried.

The sample for perspiration resistance evaluation after natural drying was left at high temperature and high humidity (120° C., 100% RH) for 15 hours.

Regarding the sample for perspiration resistance evaluation after 15 minutes, a corrosion state of the copper foil under the protective film for a touch panel was visually observed through the protective film for a touch panel. The perspiration resistance of the protective film for a touch panel was evaluated according to the following evaluation standard based on the observation results.

The results are shown in Tables 2 to 6.

In the following evaluation standards, A or B is in a practically acceptable range of the perspiration resistance of the protective film for a touch panel.

Evaluation Standard of Perspiration Resistance of Protective Film for Touch Panel

A: No corrosion of the copper foil was observed.

B: In the corrosion portion of the copper foil, a distance between the center of the corrosion portion and an end portion of the corrosion portion was smaller than 0.5 mm.

C: In the corrosion portion of the copper foil, a distance between the center of the corrosion portion and an end portion of the corrosion portion was equal to or greater than 0.5 mm and smaller than 10 mm.

D: In the corrosion portion of the copper foil, a distance between the center of the corrosion portion and an end portion of the corrosion portion was equal to or greater than 10 mm and smaller than 20 mm.

E: In the corrosion portion of the copper foil, a distance between the center of the corrosion portion and an end portion of the corrosion portion was equal to or greater than 20 mm.

TABLE 2

| | | | Example | | | | | | |
|---|---|---|---|---|---|---|---|---|---|
| | | | 1 | 2 | 3 | 4 | 5 | 6 | 7 |
| | | | Material | Material | Material | Material | Material | Material | Material |
| | Component | Material | A-1 | A-2 | A-3 | A-4 | A-5 | A-6 | A-7 |
| Material of | Polymerizable | A-DCP | 5.84 | 5.31 | | 3.98 | 5.31 | 5.31 | 5.31 |
| photosensitive | monomer | TO-2349 | 1.22 | 1.11 | 1.11 | 1.11 | 1.11 | 1.11 | 1.11 |
| layer of | | AD-TMP | | | 5.31 | | | | |
| transfer film | | A-NOD-N | | | | 1.33 | | | |
| (photosensitive | | 8UX-015A | 2.92 | 2.65 | 2.65 | 2.65 | | 2.65 | 2.65 |
| resin | | M-270 | | | | | 2.65 | | |
| composition) | Polymerization | OXE-02 | 0.10 | 0.10 | 0.10 | 0.10 | 0.10 | | |
| | initiator | IRG907 | 0.20 | 0.20 | 0.20 | 0.20 | 0.20 | 0.20 | 0.20 |
| | | IRG379EG | | | | | | 0.25 | |
| | | OXE-01 | | | | | | | 0.10 |
| | | N-phenylglycine | | | | | | | |
| | Polymer | SMA-3000P (Copolymer of styrene/maleic | 0.87 | 0.87 | 0.87 | 0.87 | 0.87 | 0.87 | 0.87 |
| | including | anhydride = 3/1 (molar ratio), acid anhydride | | | | | | | |
| | structural unit | value = 2.44 mmol/g Mw = 9,500, | | | | | | | |
| | having | manufactured by Cray Valley) | | | | | | | |
| | carboxylic | SMA-EF-40P (Copolymer of styrene/maleic | | | | | | | |
| | acid anhydride | anhydride = 4/1 (molar ratio), acid anhydride | | | | | | | |
| | structure | value = 1.94 mmol/g Mw = 10,500, | | | | | | | |
| | | manufactured by Cray Valley) | | | | | | | |
| | | SMA-EF-60P (Copolymer of styrene/maleic | | | | | | | |
| | | anhydride = 6/1 (molar ratio), acid anhydride | | | | | | | |
| | | value = 1.38 mmol/g Mw = 11,500, | | | | | | | |
| | | manufactured by Cray Valley) | | | | | | | |
| | | SMA-EF-80P (Copolymer of styrene/maleic | | | | | | | |
| | | anhydride = 8/1 (molar ratio), acid anhydride | | | | | | | |
| | | value = 1.07 mmol/g Mw = 14,400, | | | | | | | |
| | | manufactured by Cray Valley) | | | | | | | |
| | | SMA-1000P (Copolymer of styrene/maleic | | | | | | | |
| | | anhydride = 1/1 (molar ratio), acid anhydride | | | | | | | |
| | | value = 4.95 mmol/g Mw = 5,500, | | | | | | | |
| | | manufactured by Cray Valley) | | | | | | | |
| | | SMA-2000P (Copolymer of styrene/maleic | | | | | | | |
| | | anhydride = 2/1 (molar ratio), acid anhydride | | | | | | | |
| | | value = 3.26 mmol/g Mw = 7,500, | | | | | | | |
| | | manufactured by Cray Valley) | | | | | | | |
| | | Solution having 35.0% by mass | | | | | | | |
| | | of solid content of Polymer C-1 | | | | | | | |
| | | (acid anhydride value = 1.98 mmol/g) | | | | | | | |
| | Nitrogen- | Benzimidazole (manufactured by Tokyo | | | | | | | |
| | containing | Chemical Industry Co., Ltd.) | | | | | | | |
| | heterocyclic | Benzotriazole (BT 120 manufactured | | | | | | | |
| | compound | by Johoku Chemical Co., Ltd.) | | | | | | | |
| | | 5-Amino-1H-tetrazole (HAT manufactured | 0.15 | 0.15 | 0.15 | 0.15 | 0.15 | 0.15 | 0.15 |
| | | by Toyobo Co., Ltd.) | | | | | | | |
| | | 2-aminobenzothiazole (manufactured by | | | | | | | |
| | | Tokyo Chemical Industry Co., Ltd.) | | | | | | | |
| | | 2-amino-5-mercapto-1,3,4-thiadiazole | | | | | | | |
| | | (manufactured by Tokyo | | | | | | | |
| | | Chemical Industry Co., Ltd.) | | | | | | | |
| | Other polymers | Solution having 36.3% by | 48.64 | 41.16 | 41.16 | 41.16 | 41.16 | 40.75 | 41.16 |
| | | mass of solid content of | | | | | | | |
| | | Polymer D (acid value = 95 mgKOH/g) | | | | | | | |
| | | SMA-2625 | | | | | | | |
| | | (Copolymer of half ester of styrene/maleic | | | | | | | |
| | | anhydride = 2/1 (molar ratio), Mw = 9,000, | | | | | | | |
| | | manufactured by Cray Valley) | | | | | | | |
| | | SMA-17532 | | | | | | | |
| | | (Copolymer of half ester of styrene-maleic | | | | | | | |
| | | anhydride = 1/1 (molar ratio), Mw = 7,000, | | | | | | | |
| | | manufactured by Cray Valley) | | | | | | | |
| | Photopoly- | Phenothiazine (manufactured by | | | | | | | |
| | merization | Seiko Chemical Co., Ltd.) | | | | | | | |
| | inhibitor | | | | | | | | |
| | Thermal | DURANATE X3071.04 (manufactured | | 4.83 | | 4.83 | 4.83 | 4.83 | 4.83 |
| | crosslinking | by Asahi Kasei Corporation) | | | | | | | |
| | compound | DURANATE TPA-B80E (manufactured | | | 4.83 | | | | |
| | | by Asahi Kasei Corporation) | | | | | | | |
| | Surfactant | MEGAFACE F551 (manufactured | 0.05 | 0.05 | 0.05 | 0.05 | 0.05 | 0.05 | 0.05 |
| | | by DIC Corporation) | | | | | | | |
| | Solvent | Methyl ethyl ketone | 40.01 | 43.57 | 43.57 | 43.57 | 43.57 | 43.84 | 43.57 |
| | Solid content | | 29.00 | 29.00 | 29.00 | 29.00 | 29.00 | 29.00 | 29.00 |
| Evaluation | Development | Laminating temperature during transfer: 110° C. | A | A | A | A | A | A | A |
| result | residue | Laminating temperature during transfer: 120° C. | A | A | A | A | A | A | A |
| | | Laminating temperature during transfer: 130° C. | A | A | A | A | A | A | A |
| | | Laminating temperature during transfer: 140° C. | A | A | A | A | A | A | A |

| | | | | | | | |
|---|---|---|---|---|---|---|---|
| Perspiration resistance | B | A | A | A | A | A | A |

TABLE 3

| | | | Example | | | | | |
|---|---|---|---|---|---|---|---|---|
| | | | 8 | 9 | 10 | 11 | 12 | 13 |
| | | | Material | Material | Material | Material | Material | Material |
| | Component | Material | A-8 | A-9 | A-10 | A-11 | A-12 | A-13 |
| Material of | Polymerizable | A-DCP | 5.31 | 5.31 | 5.31 | 5.31 | 5.31 | 5.31 |
| photosensitive | monomer | TO-2349 | 1.11 | 1.11 | 1.11 | 1.11 | 1.11 | 1.11 |
| layer of | | AD-TMP | | | | | | |
| ftransfer film | | A-NOD-N | | | | | | |
| (photosensitive | | 8UX-015A | 2.65 | 2.65 | 2.65 | 2.65 | 2.65 | 2.65 |
| resin | | M-270 | | | | | | |
| composition) | Polymerization | OXE-02 | 0.10 | 0.10 | 0.10 | 0.10 | 0.10 | 0.10 |
| | initiator | IRG907 | 0.20 | 0.20 | 0.20 | 0.20 | 0.20 | 0.20 |
| | | IRG379EG | | | | | | |
| | | OXE-01 | | | | | | |
| | | N-phenylglycine | | | | | | |
| | Polymer including | SMA-3000P (Copolymer of styrene/maleic | | | | | | |
| | structural unit having | anhydride = 3/1 (molar ratio), acid anhydride value = | | | | | | |
| | carboxylic acid | 2.44 mmol/g Mw = 9,500, | | | | | | |
| | anhydride | manufactured by Cray Valley) | | | | | | |
| | structure | SMA-EF-40P (Copolymer of styrene/maleic | 0.87 | | | | | |
| | | anhydride = 4/1 (molar ratio), acid anhydride value = | | | | | | |
| | | 1.94 mmol/g Mw = 10,500, | | | | | | |
| | | manufactured by Cray Valley) | | | | | | |
| | | SMA-EF-60P (Copolymer of styrene/maleic | | 0.87 | | | | |
| | | anhydride = 6/1 (molar ratio), acid anhydride value = | | | | | | |
| | | 1.38 mmol/g Mw = 11,500, | | | | | | |
| | | manufactured by Cray Valley) | | | | | | |
| | | SMA-EF-80P (Copolymer of styrene/maleic | | | 0.87 | | | |
| | | anhydride = 8/1 (molar ratio), acid anhydride value = | | | | | | |
| | | 1.07 mmol/g Mw = 14,400, | | | | | | |
| | | manufactured by Cray Valley) | | | | | | |
| | | SMA-1000P (Copolymer of styrene/maleic | | | | 0.87 | | |
| | | anhydride = 1/1 (molar ratio), acid anhydride value = | | | | | | |
| | | 4.95 mmol/g Mw = 5,500, | | | | | | |
| | | manufactured by Cray Valley) | | | | | | |
| | | SMA-2000P (Copolymer of styrene/maleic | | | | | 0.87 | |
| | | anhydride = 2/1 (molar ratio), acid anhydride value = | | | | | | |
| | | 3.26 mmol/g Mw = 7,500, | | | | | | |
| | | manufactured by Cray Valley) | | | | | | |
| | | Solution having 35.0% by mass of solid content | | | | | | 2.49 |
| | | of Polymer C-1 (acid anhydride value = 1.98 | | | | | | |
| | | mmol/g) | | | | | | |
| | Nitrogen-containing | Benzimidazole (manufactured by | | | | | | |
| | heterocyclic | Tokyo Chemical Industry Co., Ltd.) | | | | | | |
| | compound | Benzotriazole (BT 120 manufactured | | | | | | |
| | | by Johoku Chemical Co., Ltd.) | | | | | | |
| | | 5-Amino-1H-tetrazole (HAT manufactured | 0.15 | 0.15 | 0.15 | 0.15 | 0.15 | 0.15 |
| | | by Toyobo Co., Ltd.) | | | | | | |
| | | 2-aminobenzothiazole (manufactured by | | | | | | |
| | | Tokyo Chemical Industry Co., Ltd.) | | | | | | |
| | | 2-amino-5-mercapto-1,3,4-thiadiazole | | | | | | |
| | | (manufactured by | | | | | | |
| | | Tokyo Chemical Industry Co., Ltd.) | | | | | | |
| | Other polymers | Solution having 36.3% by mass of solid content of | 41.16 | 41.16 | 41.16 | 41.16 | 41.16 | 41.16 |
| | | Polymer D (acid value = 95 mgKOH/g) | | | | | | |
| | | SMA-2625 (Copolymer of half ester of styrene/maleic | | | | | | |
| | | anhydride = 2/1 (molar ratio), Mw = 9,000, | | | | | | |
| | | manufactured by Cray Valley) | | | | | | |
| | | SMA-17532 (Copolymer of | | | | | | |
| | | half ester of styrene-maleic | | | | | | |
| | | anhydride = 1/1 (molar ratio), Mw = 7,000, | | | | | | |
| | | manufactured by Cray Valley) | | | | | | |
| | Photopolymerization | Phenothiazine (manufactured | | | | | | |
| | inhibitor | by Seiko Chemical Co., Ltd.) | | | | | | |
| | | DURANATE X3071.04 | 4.83 | 4.83 | 4.83 | 4.83 | 4.83 | 4.83 |
| | | (manufactured by Asahi Kasei Corporation) | | | | | | |
| | Thermal crosslinking | DURANATE TPA-B80E | | | | | | |
| | compound | (manufactured by Asahi Kasei Corporation) | | | | | | |
| | Surfactant | MEGAFACE F551 (manufactured | 0.05 | 0.05 | 0.05 | 0.05 | 0.05 | 0.05 |
| | | by DIC Corporation) | | | | | | |
| | Solvent | Methyl ethyl ketone | 43.57 | 43.57 | 43.57 | 43.57 | 43.57 | 41.96 |
| | Solid content | | 29.00 | 29.00 | 29.00 | 29.00 | 29.00 | 29.00 |
| Evaluation | Deveopment residue | Laminating temperature during transfer: 110° C. | A | A | A | A | A | A |
| result | | Laminating temperature during transfer: 120° C. | A | A | A | A | A | A |
| | | Laminating temperature during transfer: 130° C. | A | A | A | B | B | A |
| | | Laminating temperature during transfer: 140° C. | A | A | A | B | B | A |

| | | | | | | |
|---|---|---|---|---|---|---|
| Perspiration resistance | A | A | A | B | B | A |

TABLE 4

| | | | Example | | | | | | |
|---|---|---|---|---|---|---|---|---|---|
| | | | 14 | 15 | 16 | 17 | 18 | 19 | 20 |
| | | | Material | Material | Material | Material | Material | Material | Material |
| | Component | Material | A-14 | A-15 | A-16 | A-17 | A-18 | A-19 | A-20 |
| Material of | Polymerizable | A-DCP | 5.31 | 5.31 | 5.31 | 5.31 | 5.31 | 5.31 | 5.31 |
| photosensitive | monomer | TO-2349 | 1.11 | 1.11 | 1.11 | 1.11 | 1.11 | 1.11 | 1.11 |
| layer of | | AD-TMP | | | | | | | |
| transfer | | A-NOD-N | | | | | | | |
| film | | 8UX-015A | 2.65 | 2.65 | 2.65 | 2.65 | 2.65 | 2.65 | 2.65 |
| (photosensitive | | M-270 | | | | | | | |
| resin | Polymerization | OXE-02 | 0.10 | 0.10 | 0.10 | 0.10 | 0.10 | 0.10 | 0.10 |
| composition) | initiator | IRG907 | 0.20 | 0.20 | 0.20 | 0.20 | 0.20 | 0.20 | 0.20 |
| | | IRG379EG | | | | | | | |
| | | OXE-01 | | | | | | | |
| | | N-phenylglycine | | | | | | | |
| | Polymer including | SMA-3000P (Copolymer of styrene/maleic | 2.90 | 5.80 | 8.70 | 0.87 | 0.87 | 0.87 | 0.87 |
| | structural unit | anhydride = 3/1 (molar ratio), acid anhydride | | | | | | | |
| | having | value = 2.44 mmol/g Mw = 9,500, | | | | | | | |
| | carboxylic acid | manufactured by Cray Valley) | | | | | | | |
| | anhydride | SMA-EF-40P (Copolymer of styrene/maleic | | | | | | | |
| | structure | anhydride = 4/1 (molar ratio), acid anhydride | | | | | | | |
| | | value = 1.94 mmol/g Mw = 10,500, | | | | | | | |
| | | manufactured by Cray Valley) | | | | | | | |
| | | SMA-EF-60P (Copolymer of styrene/maleic | | | | | | | |
| | | anhydride = 6/1 (molar ratio), acid anhydride | | | | | | | |
| | | value = 1.38 mmol/g Mw = 11,500, | | | | | | | |
| | | manufactured by Cray Valley) | | | | | | | |
| | | SMA-EF-80P (Copolymer of styrene/maleic | | | | | | | |
| | | anhydride = 8/1 (molar ratio), acid anhydride | | | | | | | |
| | | value = 1.07 mmol/g Mw = 14,400, | | | | | | | |
| | | manufactured by Cray Valley) | | | | | | | |
| | | SMA-1000P (Copolymer of styrene/maleic | | | | | | | |
| | | anhydride = 1/1 (molar ratio), acid anhydride | | | | | | | |
| | | value = 4.95 mmol/g Mw = 5,500, | | | | | | | |
| | | manufactured by Cray Valley) | | | | | | | |
| | | SMA-2000P (Copolymer of styrene/maleic | | | | | | | |
| | | anhydride = 2/1 (molar ratio), acid anhydride | | | | | | | |
| | | value = 3.26 mmol/g Mw = 7,500, | | | | | | | |
| | | manufactured by Cray Valley) | | | | | | | |
| | | Solution having 35.0% by mass of solid content | | | | | | | |
| | | of Polymer C-1 (acid anhydride value = 1.98 | | | | | | | |
| | | mmol/g) | | | | | | | |
| | Nitrogen- | Benzimidazole (manufactured by | | | | 0.15 | | | |
| | containing | Tokyo Chemical Industry Co., Ltd.) | | | | | | | |
| | heterocyclic | Benzotriazole (BT 120 manufactured | | | | | 0.15 | | |
| | compound | by Johoku Chemical Co., Ltd.) | | | | | | | |
| | | 5-Amino-1H-tetrazole (HAT manufactured | 0.15 | 0.15 | 0.15 | | | | |
| | | by Toyobo Co., Ltd.) | | | | | | | |
| | | 2-aminobenzothiazole (manufactured by | | | | | | 0.15 | |
| | | Tokyo Chemical Industry Co., Ltd.) | | | | | | | |
| | | 2-amino-5-mercapto-1,3,4-thiadiazole | | | | | | | 0.15 |
| | | (manufactured by Tokyo | | | | | | | |
| | | Chemical Industry Co., Ltd.) | | | | | | | |
| | Other polymers | Solution having 36.3% by | 35.57 | 27.58 | 19.59 | 41.16 | 41.16 | 41.16 | 41.16 |
| | | mass of solid content of | | | | | | | |
| | | Polymer D (acid value = 95 mgKOH/g) | | | | | | | |
| | | SMA-2625 | | | | | | | |
| | | (Copolymer of half ester of styrene/maleic | | | | | | | |
| | | anhydride = 2/1 (molar ratio), Mw = 9,000, | | | | | | | |
| | | manufactured by Cray Valley) | | | | | | | |
| | | SMA-17532 | | | | | | | |
| | | (Copolymer of half ester of styrene-maleic | | | | | | | |
| | | anhydride = 1/1 (molar ratio), Mw = 7,000, | | | | | | | |
| | | manufactured by Cray Valley) | | | | | | | |
| | Photopoly- | Phenothiazine (manufactured by | | | | | | | |
| | merization | Seiko Chemical Co., Ltd.) | | | | | | | |
| | inhibitor | | | | | | | | |
| | Thermal | DURANATE X3071.04 (manufactured | 4.83 | 4.83 | 4.83 | 4.83 | 4.83 | 4.83 | 4.83 |
| | crosslinking | by Asahi Kasei Corporation) | | | | | | | |
| | compound | DURANATE TPA-B80E (manufactured | | | | | | | |
| | | by Asahi Kasei Corporation) | | | | | | | |
| | Surfactant | MEGAFACE F551 (manufactured | 0.05 | 0.05 | 0.05 | 0.05 | 0.05 | 0.05 | 0.05 |
| | | by DIC Corporation) | | | | | | | |
| | Solvent | Methyl ethyl ketone | 47.13 | 52.22 | 57.31 | 43.57 | 43.57 | 43.57 | 43.57 |
| | Solid content | | 29.00 | 29.00 | 29.00 | 29.00 | 29.00 | 29.00 | 29.00 |
| Evaluation | Development | Laminating temperature during transfer: 110° C. | A | A | A | A | A | A | A |
| result | residue | Laminating temperature during transfer: 120° C. | A | A | A | A | A | A | A |
| | | Laminating temperature during transfer: 130° C. | A | A | A | A | A | A | A |
| | | Laminating temperature during transfer: 140° C. | B | B | B | A | A | B | B |

| | | | | | | | |
|---|---|---|---|---|---|---|---|
| Perspiration resistance | A | A | B | A | A | B | B |

TABLE 5

| | | | Example | | | | | |
|---|---|---|---|---|---|---|---|---|
| | | | 21 | 22 | 23 | 24 | 25 | 26 |
| | | | Material | Material | Material | Material | Material | Material |
| | Component | Material | A-21 | A-22 | A-23 | A-24 | A-25 | A-26 |
| Material | Polymerizable | A-DCP | 5.31 | 5.31 | 5.31 | 5.31 | 5.31 | 5.31 |
| photosensitve | monomer | TO-2349 | 1.11 | 1.11 | 1.11 | 1.11 | 1.11 | 1.11 |
| layer of | | AD-TMP | | | | | | |
| transfer film | | A-NOD-N | | | | | | |
| (photosensitive | | 8UX-015A | 2.65 | 2.65 | 2.65 | 2.65 | 2.65 | 2.65 |
| resin | | M-270 | | | | | | |
| composition) | Polymerization | OXE-02 | 0.10 | 0.10 | 0.10 | 0.10 | 0.10 | 0.10 |
| | initiator | IRG907 | 0.20 | 0.20 | 0.20 | 0.20 | 0.20 | 0.20 |
| | | IRG379EG | | | | | | |
| | | OXE-01 | | | | | | |
| | | N-phenylglycine | | | 0.06 | 0.06 | | |
| | Polymer including | SMA-3000P (Copolymer a styrene/maleic | 0.87 | 0.87 | 0.87 | 0.87 | 0.70 | 0.30 |
| | structural | anhydride = 3/1 (molar ratio), acid anhydride | | | | | | |
| | unit having | value = 2.44 mmol/g Mw = 9,500, | | | | | | |
| | carboxylic acid | manufactured by Cray Valley) | | | | | | |
| | anhydride | SMA-EF-40P (Copolymer of styrene/maleic | | | | | | |
| | structure | anhydride = 4/1 (molar ratio), acid anhydride | | | | | | |
| | | value = 1.94 mmol/g Mw = 10,500, | | | | | | |
| | | manufactured by Cray Valley) | | | | | | |
| | | SMA-EF-60P (Copolymer of styrene/maleic | | | | | | |
| | | anhydride = 6/1 (molar ratio), acid anhydride | | | | | | |
| | | value = 1.38 mmol/g Mw = 11,500, | | | | | | |
| | | manufactured by Cray Valley) | | | | | | |
| | | SMA-EF-80P (Copolymer of styrene/maleic | | | | | | |
| | | anhydride = 8/1 (molar ratio), acid anhydride | | | | | | |
| | | value = 1.07 mmol/g Mw = 14,400, | | | | | | |
| | | manufactured by Cray Valley) | | | | | | |
| | | SMA-1000P (Copolymer of styrene/maleic | | | | | | |
| | | anhydride = 1/1 (molar ratio), acid anhydride | | | | | | |
| | | value = 4.95 mmol/g Mw = 5,500, | | | | | | |
| | | manufactured by Cray Valley) | | | | | | |
| | | SMA-2000P (Copolymer of styrene/maleic | | | | | | |
| | | anhydride = 2/1 (molar ratio), acid anhydride | | | | | | |
| | | value = 3.26 mmol/g Mw = 7,500, | | | | | | |
| | | manufactured by Cray Valley) | | | | | | |
| | | Solution having 35.0% by mass of solid content of | | | | | | |
| | | Polymer C-1 (acid anhydride value = 1.98 | | | | | | |
| | | mmol/g) | | | | | | |
| | Nitrogen- | Benzimidazole (manufactured by Tokyo | | | 0.15 | | | |
| | containing | Chemical Industry Co., Ltd.) | | | | | | |
| | heterocyclic | Benzotriazole (BT 120 manufactured | | | | | | |
| | compound | by Johoku Chemical Co., Ltd.) | | | | | | |
| | | 5-Amino-1H-tetrazole (HAT manufactured | 0.03 | 1.45 | | 0.15 | 0.30 | 0.70 |
| | | by Toyobo Co., Ltd.) | | | | | | |
| | | 2-aminobenzothiazole (manufactured by | | | | | | |
| | | Tokyo Chemical Industry Co., Ltd.) | | | | | | |
| | | 2-amino-5-mercapto-1,3,4-thiadiazole | | | | | | |
| | | (manufactured by | | | | | | |
| | | Tokyo Chemical Industry Co., Ltd.) | | | | | | |
| | Other polymers | Solution having 36.3% by mass of solid content of | 41.49 | 37.58 | 40.97 | 40.97 | 41.22 | 41.22 |
| | | Polymer D (acid value = 95 mgKOH/g) | | | | | | |
| | | SMA-2625 | | | | | | |
| | | (Copolymer of half ester of styrene/maleic | | | | | | |
| | | anhydride = 2/1 (molar ratio), Mw = 9,000, | | | | | | |
| | | manufactured by Cray Valley) | | | | | | |
| | | SMA-17532 | | | | | | |
| | | (Copolymer of half ester of styrene-maleic | | | | | | |
| | | anhydride = 1/1 (molar ratio), Mw = 7,000, | | | | | | |
| | | manufactured by Cray Valley) | | | | | | |
| | Photo- | Phenothiazine (manufactured by | | | 0.01 | 0.01 | | |
| | polymerization | Seiko Chemical Co., Ltd.) | | | | | | |
| | inhibitor | | | | | | | |
| | Thermal | DURANATE X3071.04 (manufactured | 4.83 | 4.83 | 4.83 | | 4.83 | 4.83 |
| | crosslinking | by Asahi Kasei Corporation) | | | | | | |
| | compound | DURANATE TPA-B80E (manufactured | | | | 4.83 | | |
| | | by Asahi Kasei Corporation) | | | | | | |
| | Surfactant | MEGAFACE F551 (manufactured | 0.05 | 0.05 | 0.05 | 0.05 | 0.05 | 0.05 |
| | | by DIC Corporation) | | | | | | |
| | Solvent | Methyl ethyl ketone | 43.36 | 45.85 | 43.69 | 43.69 | 43.54 | 43.54 |
| | Solid content | | 29.00 | 29.00 | 29.00 | 29.00 | 29.00 | 29.00 |
| Evaluation | Development | Laminating temperature during transfer: 110° C. | A | A | A | A | A | A |
| result | residue | Laminating temperature during transfer: 120° C. | A | A | A | A | A | A |
| | | Laminating temperature during transfer: 130° C. | A | A | A | A | A | A |
| | | Laminating temperature during transfer: 140° C. | B | B | A | A | A | B |

| | | | | | | |
|---|---|---|---|---|---|---|
| Perspiration resistance | A | A | A | A | A | B |

TABLE 6

| | | | Comparative Example | | | | |
|---|---|---|---|---|---|---|---|
| | | | 2 | 3 | 4 | 5 | |
| | | | Material | Material | Material | Material | Material |
| | Component | Material | A-27 | A-28 | A-29 | A-30 | A-31 |
| Material of | Polymerizable | A-DCP | 5.31 | 5.31 | 5.31 | 5.31 | 5.31 |
| photosensitive | monomer | TO-2349 | 1.11 | 1.11 | 1.11 | 1.11 | 1.11 |
| layer of | | AD-TMP | | | | | |
| transfer film | | sA-NOD-N | | | | | |
| (photosensitive | | 8UX-015A | 2.65 | 2.65 | 2.65 | 2.65 | 2.65 |
| resin | | M-270 | | | | | |
| composition) | Polymerization | OXE-02 | 0.10 | 0.10 | 0.10 | 0.10 | 0.10 |
| | initiator | IRG907 | 0.20 | 0.20 | 0.20 | 0.20 | 0.20 |
| | | IRG379EG | | | | | |
| | | OXE-01 | | | | | |
| | | N-phenylglycine | | | | | |
| | Polymer | SMA-3000P (Copolymer of styrene/maleic | | 0.87 | | | |
| | including | anhydride = 3/1 (molar ratio), acid anhydride value = 2.44 | | | | | |
| | structural | mmol/g Mw = 9,500, manufactured by Cray Valley) | | | | | |
| | unit having | SMA-EF-40P (Copolymer of styrene/maleic | | | | | |
| | carboxylic | anhydride = 4/1 (molar ratio), acid anhydride value = 1.94 | | | | | |
| | acid anhydride | mmol/g Mw = 10,500, manufactured by Cray Valley) | | | | | |
| | structure | SMA-EF-60P (Copolymer of styrene/maleic | | | | | |
| | | anhydride = 6/1 (molar ratio), acid anhydride value = 1.38 | | | | | |
| | | mmol/g Mw = 11,500, manufactured by Cray Valley) | | | | | |
| | | SMA-EF-80P (Copolymer of styrene/maleic | | | | | |
| | | anhydride = 8/1 (molar ratio), acid anhydride value = 1.07 | | | | | |
| | | mmol/g Mw = 14,400, manufactured by Cray Valley) | | | | | |
| | | SMA-1000P (Copolymer of styrene/maleic | | | | | |
| | | anhydride = 1/1 (molar ratio), acid anhydride value = 4.95 | | | | | |
| | | mmol/g Mw = 5,500, manufactured by Cray Valley) | | | | | |
| | | SMA-2000P (Copolymer of styrene/maleic | | | | | |
| | | anhydride = 2/1 (molar ratio), acid anhydride value = 3.26 | | | | | |
| | | mmol/g Mw = 7,500, manufactured by Cray Valley) | | | | | |
| | | Solution having 35.0% by mass of solid content of | | | | | |
| | | Polymer C-1 (acid anhydride value = 1.98 mmol/g) | | | | | |
| | | Benzimidazole (manufactured by | | | | | |
| | | Tokyo Chemical Industry Co., Ltd.) | | | | | |
| | Nitrogen- | Benzotriazole (BT 120 manufactured | | | | | |
| | containing | by Johoku Chemical Co., Ltd.) | | | | | |
| | heterocyclic | 5-Amino-1H-tetrazole (HAT manufactured | | | 0.15 | 0.15 | 0.15 |
| | compound | by Toyobo Co., Ltd.) | | | | | |
| | | 2-aminobenzothiazole (manufactured by | | | | | |
| | | Tokyo Chemical Industry Co., Ltd.) | | | | | |
| | | 2-amino-5-mercapto-1,3,4-thiadiazole (manufactured | | | | | |
| | | by Tokyo Chemical Industry Co., Ltd.) | | | | | |
| | Other polymers | Solution having 36.3% by mass of solid content of | 43.97 | 41.58 | 43.56 | 41.16 | 41.16 |
| | | Polymer D (acid value = 95 mgKOH/g) | | | | | |
| | | SMA-2625 | | | | 0.87 | |
| | | (Copolymer of half ester of styrene/maleic | | | | | |
| | | anhydride = 2/1 (molar ratio), Mw = 9,000, | | | | | |
| | | manufactured by Cray Valley) | | | | | |
| | | SMA-17532 | | | | | 0.87 |
| | | (Copolymer of half ester of styrene-maleic | | | | | |
| | | anhydride = 1/1 (molar ratio), Mw = 7,000, | | | | | |
| | | manufactured by Cray Valley) | | | | | |
| | Photo- | Phenothiazine (manufactured | | | | | |
| | polymerization | by Seiko Chemical Co., Ltd.) | | | | | |
| | inhibitor | | | | | | |
| | Thermal | DURANATE X3071.04 (manufactured | 4.83 | 4.83 | 4.83 | 4.83 | 4.83 |
| | crosslinking | by Asahi Kasei Corporation) | | | | | |
| | compound | DURANATE TPA-B80E (manufactured | | | | | |
| | | by Asahi Kasei Corporation) | | | | | |
| | Surfactant | MEGAFACE F551 (manufactured by DIC Corporation) | 0.05 | 0.05 | 0.05 | 0.05 | 0.05 |
| | Solvent | Methyl ethyl ketone | 41.78 | 43.31 | 42.05 | 43.57 | 43.57 |
| | Solid content | | 29.00 | 29.00 | 29.00 | 29.00 | 29.00 |
| Evaluation | Development | Laminating temperature during transfer: 110° C. | A | A | A | A | A |
| result | residue | Laminating temperature during transfer: 120° C. | B | A | B | B | B |
| | | Laminating temperature during transfer: 130° C. | C | A | C | C | C |
| | | Laminating temperature during transfer: 140° C. | C | B | C | C | C |

| | | | | | |
|---|---|---|---|---|---|
| Perspiration resistance | E | D | C | D | D |

In Tables 2 to 6, the details of the photopolymerizable monomer are as follows.

A-DCP: Tricyclodecane dimethanol diacrylate (Shin-Nakamura Chemical Co., Ltd.; difunctional monomer)

TO-2349: carboxylic acid-containing monomer (Toagosei Co., Ltd. “ARONIX (registered trademark) TO-2349”; mixture of pentafunctional monomer and hexafunctional monomer)

AD-TMP: ditrimethylolpropane tetraacrylate (Shin-Nakamura Chemical Co., Ltd.; tetrafunctional monomer)

A-NOD-N: 1,9-nonanediol diacrylate (manufactured by Shin-Nakamura Chemical Co., Ltd.; difunctional monomer)

8UX-015A: urethane acrylate (manufactured by Taisei Fine Chemical Co., Ltd.; 15-functional monomer)

M-270: polypropylene glycol diacrylate (manufactured by Toagosei Co., Ltd. “ARONIX (registered trademark) M-270”; difunctional monomer)

In Tables 2 to 6, the details of the photopolymerization initiator are as follows.

OXE-02: Ethanone, 1-[9-ethyl-6-(2-methylbenzoyl) -9H-carbazole-3-yl]-, 1-(O-acetyloxime) (BASF Japan Ltd., “IRGACURE (registered trademark) OXE-02”; oxime-based photopolymerization initiator)

IRG 907: 2-methyl-1-(4-methylthiophenyl)-2-morpholinopropan- 1-one (BASF Japan Ltd.; “IRGACURE (registered trademark) 907”; a-aminoalkylphenone-based photopolymerization initiator)

IRG 379 EG: 2-(dimethylamino) -2-[(4-methylphenyl) methyl]-1-[4-(4-morpholinyl) phenyl]-1-butanone (BASF Japan Ltd. “IRGACURE (registered trademark) 379 EG”; α-aminoalkylphenone-based photopolymerization initiator)

OXE-01: 1,2-octanedione, 1-[4-(phenylthio)-, 2-(O-benzoyloxime)] (BASF Japan Ltd. “IRGACURE (registered trademark) OXE-01”; oxime-based photopolymerization initiator)

N-phenylglycine; compound manufactured by Junsei Chemical Co., Ltd.

In Tables 2 to 6, a copolymerization ratio of the polymer is a molar ratio.

All of the thermal crosslinking compounds in Tables 2 to 6 (DURANATE (registered trademark) X3071.04 and DURANATE (registered trademark) TPA-B80E) are hexamethylene diisocyanate-based blocked isocyanate compounds.

As shown in Tables 2 to 5, in Examples 1 to 26 in which the photosensitive resin composition including the photopolymerizable monomer including an ethylenically unsaturated group, the photopolymerization initiator, the polymer including a structural unit having a carboxylic acid anhydride structure, and the nitrogen-containing heterocyclic compound is used, the development residue was prevented, and the protective film for a touch panel having excellent perspiration resistance could be formed.

On the other hand, as shown in Table 6, in Comparative Examples 1 and 3 to 5 in which the photosensitive resin composition not including the polymer including a structural unit having a carboxylic acid anhydride structure was used, the development residue and the perspiration resistance of the protective film for a touch panel were deteriorated. Particularly, Comparative Examples 4 and 5 are examples in which the photosensitive resin composition including a polymer including a structural unit having a carboxylic acid half ester structure, but not including the polymer including a structural unit having a carboxylic acid anhydride structure was used, and in Comparative Examples 4 and 5, it is found that the effect of preventing the development residue and the effect of improving the perspiration resistance were not obtained.

As shown in Table 6, in Comparative Example 2 in which the photosensitive resin composition including the polymer including a structural unit having a carboxylic acid anhydride structure, but not including the nitrogen-containing heterocyclic compound was used, the perspiration resistance of the protective film for a touch panel was deteriorated.

### Examples 8-2

<Formation of Protective Film for Touch Panel Due to Slit Coating>

The material A-8 used in Example 8 was slit-coated and dried on a pet film (manufactured by GEOMATEC Co., Ltd.) on which copper foil is laminated, and accordingly, a photosensitive layer having a dried film thickness of 8.0 μm was formed.

The entire surface of the photosensitive layer was exposed using a proximity type exposure device including an ultrahigh pressure mercury lamp (manufactured by Hitachi High-Tech Electronics Engineering Co., Ltd.) under the condition of an exposure intensity of 100 mJ/cm² (i ray).

The photosensitive layer after the entire surface exposure was developed using an aqueous solution having a concentration of sodium carbonate of 2% by mass (liquid temperature of 30° C.) as the developer for 40 seconds. After the development, moisture was removed by blowing air, a heating (post baking) process at 145° C. was performed for 30 minutes, and accordingly, a protective film for a touch panel was formed.

By doing so, a sample for perspiration resistance evaluation having a laminated structure of protective film for a touch panel/copper foil/PET film was obtained.

The evaluation of the perspiration resistance which is the same as in Example 8 was performed using the obtained sample for perspiration resistance evaluation (Example 8-2), and the result of “A” was obtained in the same manner as in Example 8.

### Example 24-2

In Example 24, a transfer film was obtained in the same manner as in Example 24, except that the temporary support was changed to a polyethylene terephthalate film having a thickness of 16 μm (FB-40, manufactured by Toray Industries, Inc.) and the protective film was changed to a polyethylene film having a thickness of 33 μm (GF-858, manufactured by Tamapoly Co., Ltd.), respectively.

The evaluation was performed in the same manner as in Example 24, except that the obtained transfer film was used.

As a result, the same result as in Example 24 (that is, the result of the development residue was “A” and the result of the perspiration resistance was “A”) was obtained.

### Examples 101 to 126 and Comparative Examples 101 to 105

The operation same as each of Examples 1 to 26 and Comparative Examples 1 to 5 was performed, except that the transfer film having a laminated structure of protective film/photosensitive layer/temporary support was changed to a transfer film having a laminated structure of protective film/refractive index adjusting layer/photosensitive layer/temporary support.

In Examples 101 to 126 and Comparative Examples 101 to 105, the material B-1 having the composition shown in Table 7 was used as the material of the refractive index adjusting layer.

In Examples 101 to 126 and Comparative Examples 101 to 105, the transfer film having a laminated structure of protective film/refractive index adjusting layer/photosensitive layer/temporary support was manufactured as follows.

A coated film was obtained by applying a photosensitive resin composition (specifically, any one of materials A-1 to A-31) onto a polyethylene terephthalate (PET) film having a thickness of 16 μm as the temporary support using a slit-shaped nozzle, and dried at a drying temperature of 100° C., and accordingly, a photosensitive layer was formed. Here, a coating amount of the photosensitive resin composition was adjusted so that a film thickness after drying becomes 8.0 μm.

Next, a coated film was obtained by applying the material B-1 which is the material for forming a refractive index adjusting layer on the photosensitive layer using a slit-shaped nozzle, and dried at a drying temperature of 100° C., and accordingly, a refractive index adjusting layer was formed. Here, a coating amount of the material B-1 was adjusted so that a film thickness after drying (film thickness of refractive index adjusting layer) becomes 80 nm.

Then, by pressing a protective film (polypropylene film having a thickness of 12 μm) on the refractive index adjusting layer, a transfer film having a laminated structure of protective film/refractive index adjusting layer/photosensitive layer/temporary support was obtained.

In Examples 101 to 126 and Comparative Examples 101 to 105, the laminating of the transfer film was performed by peeling off the protective film from the transfer film to expose the refractive index adjusting layer and using the transfer film from which the refractive index adjusting layer was exposed.

In Examples 101 to 126 and Comparative Examples 101 to 105, the evaluation of the development residue was performed using a touch panel having a laminated structure of protective film for a touch panel/refractive index adjusting layer/ITO transparent electrode pattern/refractive index adjusting layer/COP substrate.

In Examples 101 to 126 and Comparative Examples 101 to 105, the evaluation of the perspiration resistance was performed using the sample for perspiration resistance evaluation having a laminated structure of protective film for a touch panel/refractive index adjusting layer/copper foil/PET substrate.

The above result is shown in Table 8.

### Example 127

The same operation as in example 102 was performed, except that the material B-1 which is the material for forming a refractive index adjusting layer was changed to the material B-2 having the composition shown in Table 7.

The above result is shown in Table 8.

TABLE 7

| | Material | Material |
|---|---|---|
| Material | B-1 | B-1 |
| NANOUSE OZ-S30M: ZrO₃ particles methanol | 4.36 | — |
| dispersion liquid (non-volatilized amount | | |
| 30.5% by mass) manufactured by Nissan Chemical | | |
| Industries, Ltd. | | |
| Ammonia water (2.5% by mass) | 0.24 | 0.24 |
| Copolymer resin of methacrylic acid/allyl methacrylate | 5.27 | 9.17 |
| (weight-average molecular weight: 25,000, | | |
| composition ratio = 40/60 (mol %) | | |
| ARUFON UC-3920 | 0.05 | 0.05 |
| (manufactured by Toagosei Co., Ltd.) | | |
| Carboxylic acid-containing monomer ARONIX | 0.03 | 0.50 |
| TO-2349 (manufactured by Toagosei Co., Ltd.) | | |
| Benzotriazole BT 120 | 0.03 | 0.03 |
| (manufactured by Johoku Chemical Co., Ltd.) | | |
| MEGAFACE F444 (manufactured by DIC | 0.01 | 0.01 |
| Corporation) | | |
| Ion exchange water | 25.00 | 30.00 |
| Methanol | 65.00 | 60.00 |
| Total (parts by mass) | 100.00 | 100.00 |

TABLE 8

| | | | Evaluation result | | | | |
|---|---|---|---|---|---|---|---|
| | Material of | | Development residue | | | | Per- |
| | transfer film | | Laminating | | | | spi- |
| | | Refractive | temperature during | | | | ra- |
| | Photo- | index | transfer | | | | tion |
| | sensitive | adjusting | 110° | 120° | 130° | 140° | resist- |
| | layer | layer | C. | C. | C. | C. | ance |
| Example101 | Material | Material | A | A | A | A | B |
| | A-1 | B-1 | | | | | |
| Example102 | Material | Material | A | A | A | A | A |
| | A-2 | B-1 | | | | | |
| Example103 | Material | Material | A | A | A | A | A |
| | A-3 | B-1 | | | | | |
| Example104 | Material | Material | A | A | A | A | A |
| | A-4 | B-1 | | | | | |
| Example105 | Material | Material | A | A | A | A | A |
| | A-5 | B-1 | | | | | |
| Example106 | Material | Material | A | A | A | A | A |
| | A-6 | B-1 | | | | | |
| Example107 | Material | Material | A | A | A | A | A |
| | A-7 | B-1 | | | | | |
| Example108 | Material | Material | A | A | A | A | A |
| | A-8 | B-1 | | | | | |
| Example109 | Material | Material | A | A | A | A | A |
| | A-9 | B-1 | | | | | |
| Example110 | Material | Material | A | A | A | A | A |
| | A-10 | B-1 | | | | | |
| Example111 | Material | Material | A | A | B | B | B |
| | A-11 | B-1 | | | | | |
| Example112 | Material | Material | A | A | B | B | B |
| | A-12 | B-1 | | | | | |
| Example113 | Material | Material | A | A | A | A | A |
| | A-13 | B-1 | | | | | |
| Example114 | Material | Material | A | A | A | B | A |
| | A-14 | B-1 | | | | | |
| Example115 | Material | Material | A | A | A | B | A |
| | A-15 | B-1 | | | | | |
| Example116 | Material | Material | A | A | A | B | B |
| | A-16 | B-1 | | | | | |
| Example117 | Material | Material | A | A | A | A | A |
| | A-17 | B-1 | | | | | |
| Example118 | Material | Material | A | A | A | A | A |
| | A-18 | B-1 | | | | | |
| Example119 | Material | Material | A | A | A | B | B |
| | A-19 | B-1 | | | | | |
| Example120 | Material | Material | A | A | A | B | B |
| | A-20 | B-1 | | | | | |
| Example121 | Material | Material | A | A | A | B | A |
| | A-21 | B-1 | | | | | |
| Example122 | Material | Material | A | A | A | B | A |
| | A-22 | B-1 | | | | | |
| Example123 | Material | Material | A | A | A | A | A |
| | A-23 | B-1 | | | | | |
| Example124 | Material | Material | A | A | A | A | A |
| | A-24 | B-1 | | | | | |
| Example125 | Material | Material | A | A | A | A | A |
| | A-25 | B-1 | | | | | |
| Example126 | Material | Material | A | A | A | B | B |
| | A-26 | B-1 | | | | | |
| Example127 | Material | Material | A | A | A | A | A |
| | A-2 | B-2 | | | | | |
| Comparative | Material | Material | A | B | C | C | E |
| Example101 | A-27 | B-1 | | | | | |
| Comparative | Material | Material | A | A | A | B | D |
| Example102 | A-28 | B-1 | | | | | |
| Comparative | Material | Material | A | B | C | C | C |
| Example103 | A-29 | B-1 | | | | | |
| Comparative | Material | Material | A | B | C | C | D |
| Example104 | A-30 | B-1 | | | | | |
| Comparative | Material | Material | A | B | C | C | D |
| Example105 | A-31 | B-1 | | | | | |

As shown in Table 8, in Examples 101 to 126 and Comparative Examples 101 to 105 in which the transfer film having a laminated structure of protective film/refractive index adjusting layer/photosensitive layer/temporary support was used, the same result as in Examples 1 to 26 and Comparative Examples 1 to 5 is also obtained.

In addition, the same result was obtained in Example 102 in which B-1 was used as the material for forming a refractive index adjusting layer and Example 127 in which B-2 was used as the material for forming a refractive index adjusting layer.

From the above point, even in a case where the refractive index adjusting layer was present, it was confirmed that the effect of the disclosure (that is, the effect of improving perspiration resistance and the effect of preventing the development residue due to thermal fogging at the time of laminating) was exhibited.

A liquid crystal display apparatus including the touch panel can be manufactured by bonding the touch panel manufactured in each example described above to a liquid crystal display element manufactured by a method disclosed in paragraphs [0097] to [0119] of JP2009-047936A, for example.

The contents of JP2016-168425A filed on Aug. 30, 2016 are incorporated herein by reference.

All of the documents, the patent applications, and the technology standards described here are incorporated here by reference.

What is claimed is:

1. A photosensitive resin composition comprising:
a photopolymerizable monomer including an ethylenically unsaturated group;
a photopolymerization initiator;
a polymer including a structural unit having a carboxylic acid anhydride structure; and
a nitrogen-containing heterocyclic compound.

2. The photosensitive resin composition according to claim 1,
wherein the nitrogen-containing heterocyclic compound is at least one kind of azole compound selected from the group consisting of an imidazole component, a triazole compound, a tetrazole compound, a thiazole compound, and a thiadiazole compound.

3. The photosensitive resin composition according to claim 1,
wherein an acid anhydride value of the polymer including the structural unit having the carboxylic acid anhydride structure is 0.80 mmol/g to 5.00 mmol/g.

4. The photosensitive resin composition according to claim 1,
wherein the polymer including the structural unit having the carboxylic acid anhydride structure further includes a structural unit derived from a styrene compound.

5. The photosensitive resin composition according to claim 1,
wherein the structural unit having the carboxylic acid anhydride structure includes at least one of a structural unit represented by Formula a2-1 and a structural unit represented by Formula a2-2.

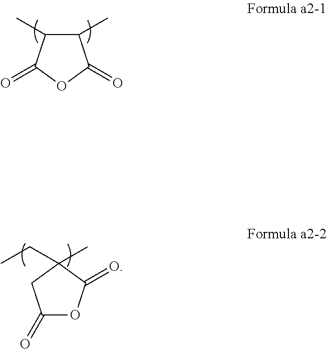

6. The photosensitive resin composition according to claim 1,
wherein a content of the polymer including the structural unit including the carboxylic acid anhydride with respect to solid contents of the photosensitive resin composition is equal to or smaller than 30% by mass.

7. The photosensitive resin composition according to claim 1,
wherein the nitrogen-containing heterocyclic compound includes at least one kind of azole compound selected from the group consisting of an imidazole compound, a triazole compound, and a tetrazole compound.

8. The photosensitive resin composition according to claim 5,
wherein the nitrogen-containing heterocyclic compound is at least one kind of azole compound selected from the group consisting of an imidazole component, a triazole compound, and a tetrazole compound,
the polymer including the structural unit having the carboxylic acid anhydride structure further includes a structural unit derived from a styrene compound,
an acid anhydride value of the polymer including the structural unit having the carboxylic acid anhydride structure is 0.80 mmol/g to 5.00 mmol/g, and
a content of the polymer including the structural unit including the carboxylic acid anhydride with respect to solid contents of the photosensitive resin composition is equal to or smaller than 30% by mass.

9. The photosensitive resin composition according to claim 1, which is used for forming a protective film for a touch panel.

10. The photosensitive resin composition according to claim 8, which is used for forming a protective film for a touch panel.

11. A transfer film comprising:
a temporary support; and
a photosensitive layer including solid contents of the photosensitive resin composition according to claim 1.

12. The transfer film according to claim 11,
wherein a thickness of the photosensitive layer is equal to or smaller than 20 μm.

13. The transfer film according to claim 12, which is used for forming a protective film for a touch panel.

14. A protective film for a touch panel which is a cured product of solid contents of the photosensitive resin composition according to claim 9.

15. A protective film for a touch panel which is a cured product of solid contents of the photosensitive resin composition according to claim 10.

16. A touch panel comprising:
the protective film for a touch panel according to claim 14.

17. A touch panel comprising:
the protective film for a touch panel according to claim 15.

18. An image display apparatus comprising:
the touch panel according to claim 16.

19. A manufacturing method of a touch panel comprising:
a step of preparing a substrate for a touch panel including a structure in which at least one of an electrode for a touch panel or a wiring for a touch panel is disposed on the substrate;
a step of forming a photosensitive layer on a surface of the substrate for a touch panel on a side where at least one of the electrode for a touch panel or the wiring for a touch panel is disposed, by using the photosensitive resin composition according to claim 9;
a step of performing pattern-exposing on the photosensitive layer formed on the surface of the substrate for a touch panel; and
a step of developing the pattern-exposed photosensitive layer to obtain a protective film for a touch panel which protects at least a part of at least one of the electrode for a touch panel or the wiring for a touch panel.

20. A manufacturing method of a touch panel comprising:
a step of preparing a substrate for a touch panel including a structure in which at least one of an electrode for a touch panel or a wiring for a touch panel is disposed on the substrate;
a step of forming a photosensitive layer on a surface of the substrate for a touch panel on a side where at least one of the electrode for a touch panel or the wiring for a touch panel is disposed, by using the photosensitive resin composition according to claim 10;
a step of performing pattern-exposing on the photosensitive layer formed on the surface of the substrate for a touch panel; and
a step of developing the pattern-exposed photosensitive layer to obtain a protective film for a touch panel which protects at least a part of at least one of the electrode for a touch panel or the wiring for a touch panel.
